(19) United States
(12) Patent Application Publication
(10) Pub. No.: US 2025/0324533 A1
(43) Pub. Date: Oct. 16, 2025

(54) HEAT SINKS FOR CAGE RECEPTABLE ASSEMBLY

(71) Applicant: MELLANOX TECHNOLOGIES, LTD., Yokneam (IL)

(72) Inventors: Erez Katz, Zur Yizhaq (IL); Andrey Ger, Shlomi (IL); Rachel Ruvel, Qriyat Ata (IL); Yair Shoham, Yokneam Illith (IL)

(21) Appl. No.: 19/095,910

(22) Filed: Mar. 31, 2025

Related U.S. Application Data
(60) Provisional application No. 63/633,650, filed on Apr. 12, 2024.

(51) Int. Cl. H05K 7/14; H05K 7/20

(52) U.S. Cl. CPC H05K 7/1425; H05K 7/20409; H05K 7/20509

(57) ABSTRACT

Apparatuses and associated methods of manufacturing are described that provide a cage receptacle assembly configured to receive a cable connector. An illustrative cage receptacle assembly is described to include a cage body, a first heat dissipation unit disposed proximate to a bottom side of the cage body and configured to remove heat from the bottom side of the cage body, and a second heat dissipation unit disposed proximate to a top side of the cage body and configured to remove heat from the top side of the cage body.

### CROSS-REFERENCE TO RELATED APPLICATION

The present application claims the benefit of and priority, under 35 U.S.C. § 119, to U.S. Provisional Application Ser. No. 63/633,650, filed Apr. 12, 2024, entitled “DUAL RIDING HEATSINK CAGE RECEPTACLE ASSEMBLY” the entire disclosure of which is hereby incorporated herein by reference, in its entirety, for all that it teaches and for all purposes.

### FIELD OF THE DISCLOSURE

The present disclosure is generally directed toward connector assemblies associated with heat dissipation units. In particular, cages, shells, and housings of connector and receptacle assemblies are described, which utilize heat dissipation units and elements that are configured to increase thermal performance.

### BACKGROUND

Datacenter switch systems and associated modules may include connections between other switch systems, servers, racks, and devices. Such connections may be made using cables, transceivers, cage receptacles, and connector assemblies, which may include a shell or housing configured to protect these connections from damage.

As datacenters continue to operate at higher speeds (e.g., 100 Gb and beyond), the thermal demands on the components in the datacenters increase as well. Heat generation in datacenters occurs primarily due to the electricity used by servers, storage devices, and other hardware components, where nearly all the consumed energy is converted into heat as a byproduct of processing data, essentially meaning that for every watt of electricity used, a watt of heat is produced. The heat requires active and continuous management; otherwise, components of the datacenter may fail under extreme thermal loads. For instance, cage receptacles can generate heat during operation, which can result in the failure of system components connected thereto.

### GENERAL DESCRIPTION

Embodiments of the present disclosure aim to address at least some issues associated with thermal loads in a datacenter. Specifically, and without limitation, embodiments of the present disclosure provide a cage receptacle assembly having improved heat distribution capabilities. Whereas previous solutions only provided a heat dissipation unit on one side of the cage body (e.g., the top of the cage body), embodiments of the present disclosure also provides a heat dissipation unit on a second side of the cage body (e.g., a bottom of the cage body). Aspects of the present disclosure may include multiple heat dissipation units secured to a cage body by a single securing element (e.g., a force mechanism and/or spring). In addition to providing improved heat distribution capabilities, the proposed cage receptacle assembly also simplifies the assembly process by allowing both heat dissipation units to be independently adjustable and by minimizing the number of pieces required to secure the multiple heat dissipation units to the cage body.

In some embodiments, apparatuses and associated methods of manufacturing are described that provide a cage receptacle assembly configured to receive a cable connector. The cage receptacle assembly includes a cage body and at least one floating heat dissipation unit (e.g., heat sink). As used herein, a floating heat dissipation unit may refer to a component or collection of components that enable a heat sink or collection of heat sinks to assume a first position relative to other components of a cage receptacle assembly when a cable connector is not inserted into a cage body of the cage receptacle assembly, but then assume a second position (e.g., different from the first position) when a cable connector is inserted into a cage body of the cage receptacle assembly. The second position of the floating heat dissipation unit may correspond to a position that is farther from a center of the cage body as compared to the first position because the cable connector, when inserted into the cage body, may cause the floating heat dissipation unit(s) to float or accommodate the cable connector (e.g., move outward from a center of the cage body).

In embodiments, the cage receptacle assembly (also referred to as a cage assembly herein) includes a first heat dissipation unit disposed on a first side (e.g., bottom side) of a printed circuit board (PCB), and a cage body disposed on a second side (e.g., top side) of the PCB. In some embodiments, the cage receptacle assembly further includes a second heat dissipation unit disposed above the cage body, and a securing element that secures both the first heat dissipation unit and the second heat dissipation unit to the cage body, where the first and second heat dissipation units are independently adjustable relative to the cage body. In some embodiments, the cage body may be formed from a unitary piece of material. For example, the cage body may be molded as a single piece of metal. In some embodiments, the cage body may be formed from two or more pieces of material, which may be joined to one another via welding, friction fit, screws, bolts, or the like.

Datacenter switch systems and associated modules may generally include connections between other switch systems, servers, racks, and devices. Such connections may be made using cables, transceivers, cage receptacles, and connector assemblies, which may include a shell or housing configured to protect these connections from damage. Often, these cage receptacles can generate heat during operation, which can result in the failure of system components.

Accordingly, the apparatuses and methods of manufacturing described herein provide a cage receptacle assembly configured to receive a cable connector. In some embodiments, the cage receptacle assembly may include a cage body that defines a receiving space configured to at least partially receive a cable connector therein. The cage receptable assembly may further include at least two floating heat dissipation units. The heat dissipation units are independently adjustable relative to the cage body (e.g., “floating”), so that their respective spatial position and orientation state is derived from the position and orientation of the respective top or bottom surfaces of the plugged transceiver. This configuration achieves effective heat transfer from the transceiver surfaces to the heat dissipation elements. The cage receptacle assembly has a first end that receives the cable connector, and a second end, opposite to the first end that may be configured to be received by a datacenter rack for enabling signals to pass between the cable connector that is at least partially received therein and the datacenter rack.

In embodiments, the cage receptacle assembly may further include a Printed Circuit Board (PCB) assembly. The PCB assembly may also define a corresponding opening configured to substantially align with the bottom opening of the cage body. In other words, the cage body may attach to the top side of the PCB.

In other cases, in an instance in which the cable connector is at least partially received within the cage body, the cage receptacle assembly may further be configured such that the heat dissipation unit(s) contact the cable connector.

In some embodiments, the cable connector may be any pluggable connector (e.g., an Octal Small Form-factor Pluggable (OSFP) or Quad Small Form-factor Pluggable (QSFP) cable connector).

Example aspects of the present disclosure include:

A cage receptacle assembly including: a cage body; a first heat dissipation unit disposed proximate to a bottom side of the cage body and configured to remove heat from the bottom side of the cage body; and a second heat dissipation unit disposed proximate to a top side of the cage body and configured to remove heat from the top side of the cage body.

In some embodiments, the cage receptacle assembly further includes a Printed Circuit Board (PCB).

In some embodiments, the first heat dissipation unit is provided on a bottom side of the PCB and extends through a hole of the PCB.

In some embodiments, the cage body includes a hole on a bottom side thereof that substantially aligns with the hole of the PCB and the first heat dissipation unit extends through the hole of the cage body.

In some embodiments, the first heat dissipation unit is configured to contact a bottom side of a cable connector inserted into the cage body.

In some embodiments, the cage body is provided on a top side of the PCB.

In some embodiments, the bottom side of the cage body abuts the top side of the PCB and wherein the top side of the cage body comprises an opening though which the second heat dissipation unit is configured to extend through to contact a top side of the cable connector.

In some embodiments, the cage receptacle assembly further includes a first portion of a securing element that wraps around at least a portion of the first heat dissipation unit and that secures the first heat dissipation unit to the cage body.

In some embodiments, the cage receptacle assembly further includes a second portion of the securing element that wraps around at least a portion of the second heat dissipation unit and that secures the second heat dissipation unit to the cage body.

In some embodiments, the first portion of the securing element and the second portion of the securing element cooperate to secure the first heat dissipation unit and the second heat dissipation unit to the cage body.

In some embodiments, the first portion of the securing element and the second portion of the securing element cooperate to secure the first heat dissipation unit and the second heat dissipation unit to a Printed Circuit Board (PCB) on which the cage body is provided.

In some embodiments, the cage receptacle assembly is configured to receive a cable connector, the cable connector may include an octal small form factor pluggable (OSFP) or a quad small form factor pluggable (QSFP).

In some embodiments, the cage body is constructed of sheet metal.

In some embodiments, the first heat dissipation unit includes a first portion and a second portion, where the first portion of the first heat dissipation unit extends through a hole of the cage body, and where the second portion of the first heat dissipation unit comprises a finned structure.

In some embodiments, the second heat dissipation unit includes a finned structure.

In some embodiments, the first heat dissipation unit includes a portion of a securing element integrated therewith.

In some embodiments, the second heat dissipation unit includes a portion of a securing element integrated therewith.

In some embodiments, the cage receptacle assembly further includes: a securing element that secures the first heat dissipation unit and/or the second heat dissipation unit to the cage body such that one or both of the first heat dissipation unit and the second heat dissipation unit are independently adjustable relative to the cage body.

In some embodiments, the securing element includes a first portion and a second portion that cooperate with one another to flexibly hold the first heat dissipation unit and the second heat dissipation unit to the cage body in a manner that accommodates a cable connector to move one or both of the first heat dissipation unit and the second heat dissipation unit when the cable connector is inserted into the cage body.

In another aspect, a method is provided, that includes: providing a first heat dissipation unit on a first side of a cage body; providing a second heat dissipation unit on a second side of the cage body; and securing the first and second heat dissipation units to the cage body in a manner that accommodates a cable connector to move one or both of the first heat dissipation unit and the second heat dissipation unit when the cable connector is inserted into the cage body.

Any aspect in combination with any one or more other aspects.

Any one or more of the features disclosed herein.

Any one or more of the features as substantially disclosed herein.

Any one or more of the features as substantially disclosed herein in combination with any one or more other features as substantially disclosed herein.

Any one of the aspects/features/implementations in combination with any one or more other aspects/features/implementations.

Use of any one or more of the aspects or features as disclosed herein.

It is to be appreciated that any feature described herein can be claimed in combination with any other feature(s) as described herein, regardless of whether the features come from the same described implementation.

The details of one or more aspects of the disclosure are set forth in the accompanying drawings and the description below. Other features, objects, and advantages of the techniques described in this disclosure will be apparent from the description and drawings, and from the claims.

Numerous additional features and advantages of the present disclosure will become apparent to those skilled in the art upon consideration of the implementation descriptions provided hereinbelow.

Additional features and advantages are described herein and will be apparent from the following Description and the figures.

### BRIEF DESCRIPTION OF THE SEVERAL VIEWS OF THE DRAWINGS

Having thus described the disclosure in general terms, reference will now be made to the accompanying drawings, which are not necessarily drawn to scale:

FIG. 1A is a block diagram illustrating an example network architecture according to at least some embodiments of the present disclosure;

FIG. 1B schematically illustrates various components of a network architecture according to at least some embodiments of the present disclosure;

FIG. 1C is a block diagram illustrating details of network devices according to at least some embodiments of the present disclosure;

FIG. 2A is a block diagram illustrating one example of a network topology according to at least some embodiments of the present disclosure;

FIG. 2B is a block diagram illustrating another example of a network topology according to at least some embodiments of the present disclosure;

FIG. 3 is a block diagram illustrating further details of a datacenter and components thereof according to at least some embodiments of the present disclosure;

FIG. 4 is a perspective view of a datacenter rack according to at least some embodiments of the present disclosure;

FIG. 5A is a top view of a transceiver module according to at least some embodiments of the present disclosure;

FIG. 5B is a perspective view of the transceiver module according to at least some embodiments of the present disclosure;

FIG. 6 is a block diagram illustrating an example of a cage receptacle assembly according to at least some embodiments of the present disclosure;

FIG. 7A is a top perspective view of one example of a cage receptacle assembly;

FIG. 7B provides a top and bottom perspective view of one example of a cable connector that can be plugged into a cage receptacle assembly according to at least some embodiments of the present disclosure;

FIG. 7C provides a top perspective view of another example of a cable connector that can be plugged into a cage receptacle assembly according to at least some embodiments of the present disclosure;

FIG. 8A provides a top perspective view of another cage receptacle assembly according to at least some embodiments of the present disclosure;

FIG. 8B provides a first exploded view of the cage receptacle assembly shown in FIG. 8A;

FIG. 8C provides a second exploded view of the cage receptacle assembly shown in FIG. 8A;

FIG. 8D provides a top perspective view of a cage body according to at least some embodiments of the present disclosure;

FIG. 8E provides a perspective view of a PCB according to at least some embodiments of the present disclosure;

FIG. 9A provides a top perspective view of a cage body with a securing element according to at least some embodiments of the present disclosure;

FIG. 9B provides a top perspective view of a cage body secured to a PCB according to at least some embodiments of the present disclosure;

FIG. 9C provides a bottom perspective view of a cage body secured to a PCB according to at least some embodiments of the present disclosure;

FIG. 9D provides a details perspective view of the cage body and the securing element according to at least some embodiments of the present disclosure;

FIG. 10 provides an exploded view of elements of a securing element according to at least some embodiments of the present disclosure;

FIG. 11A illustrates a thermal performance of a cage receptacle assembly without a bottom heat dissipation unit according to at least some embodiments of the present disclosure;

FIG. 11B illustrates a thermal performance of a cage receptacle assembly having a bottom heat dissipation unit according to at least some embodiments of the present disclosure;

FIG. 12A illustrates a front view of a cage body having a single heat dissipation unit mounted in proximity thereto according to at least some embodiments of the present disclosure;

FIG. 12B illustrates a bottom view of a PCB that receives the cage body shown in FIG. 12A;

FIG. 13A illustrates a front view of a cage body having multiple heat dissipation units mounted in proximity thereto according to at least some embodiments of the present disclosure;

FIG. 13B illustrates a bottom view of a PCB that receives the cage body shown in FIG. 13A;

FIG. 14 is a flow diagram illustrating a method of manufacturing a cage receptacle assembly according to at least some embodiments of the present disclosure;

FIG. 15 illustrates one example environment in which embodiments of the present disclosure may be deployed;

FIG. 16 illustrates another example environment in which embodiments of the present disclosure may be deployed; and

FIG. 17 illustrates another example environment in which embodiments of the present disclosure may be deployed.

Like reference numbers and designations in the various drawings may indicate like elements.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It is understood that various changes may be made in the function and arrangement of elements without departing from the spirit and scope of the appended claims.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

Various aspects of the present disclosure will be described herein with reference to drawings that are schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

The present disclosure now will be described more fully hereinafter with reference to the accompanying figures in which some but not all embodiments of the disclosures are shown. Indeed, the present disclosure may be embodied in many different forms and should not be construed as limited to the embodiments set forth herein.

Like numbers refer to like elements throughout. As used herein, terms such as “front,” “rear,” “top,” etc. are used in the examples provided below to describe the position of certain components or portions of components in an installed and operational configuration. As used herein, the term “module” encompasses hardware, software and/or firmware configured to perform one or more particular functions, including but not limited to conversion between electrical and optical signals and transmission of the same. As would be evident to one of ordinary skill in the art in light of the present disclosure, the term “substantially” indicates that the referenced element or associated description is accurate to within applicable engineering tolerances.

As discussed herein, the example embodiment is described with reference to a pluggable connector such as an octal small form factor pluggable (OSFP); however the embodiments of the present disclosure may equally be applicable to a Quad Small Form-factor Pluggable (QSFP) connector as the cable connector or any connector (e.g., Small Form Pluggable (SFP), C-Form-factor Pluggable (CFP), and the like). Moreover, the embodiments of the present disclosure may also be used with any cable (e.g., passive copper cable (PCC), active copper cable (ACC), or the like) or interconnect utilized by datacenter racks and associated switch modules (e.g., an active optical module (AOM), QSFP transceiver module, or the like).

Additionally, as discussed herein, the example embodiment is described with reference to a vertical-cavity surface-emitting laser (VCSEL) as an element of a transceiver system; however, embodiments of the present disclosure may be equally applicable for use with any transceiver system and/or element. Still further, as discussed herein, the example embodiment is described with reference to a switch module configured to receive a cage receptacle assembly to allow signals to pass between a cable connector and the switch module. The present disclosure, however, contemplates that a network interface, a high-capacity adapter, or any other applicable networking interface may equally be used instead or in conjunction with the switch module to receive the cage receptacle.

Embodiments of the present disclosure are contemplated to be deployed in a datacenter environment. While embodiments will be described in connection with certain examples of datacenter environments, it should be appreciated that embodiments of the present disclosure are not so limited. Indeed, embodiments of the present disclosure contemplate the ability to deploy a cage receptacle assembly in any number of environments including a datacenter environment or any other suitable environment in which machine-to-machine communications are facilitated.

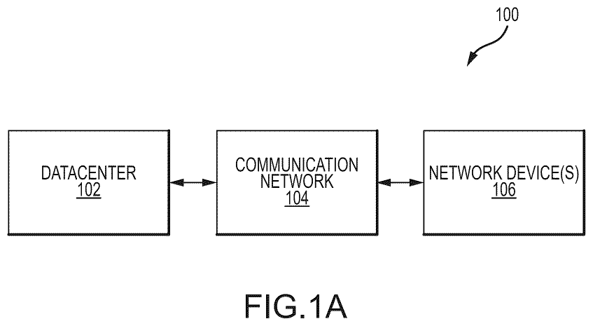

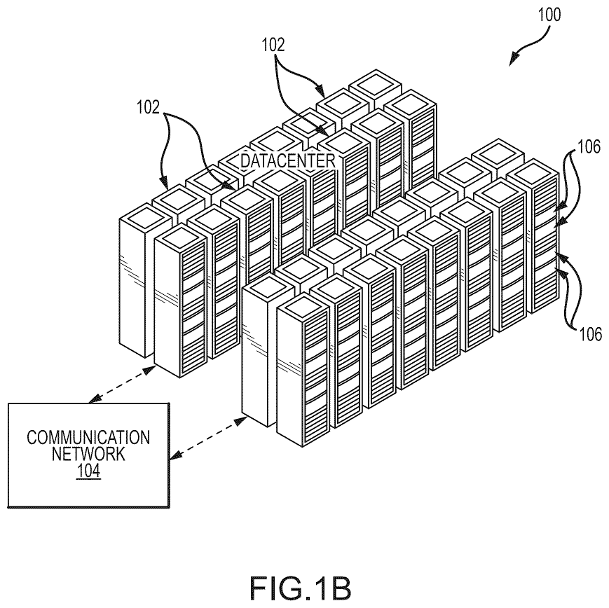

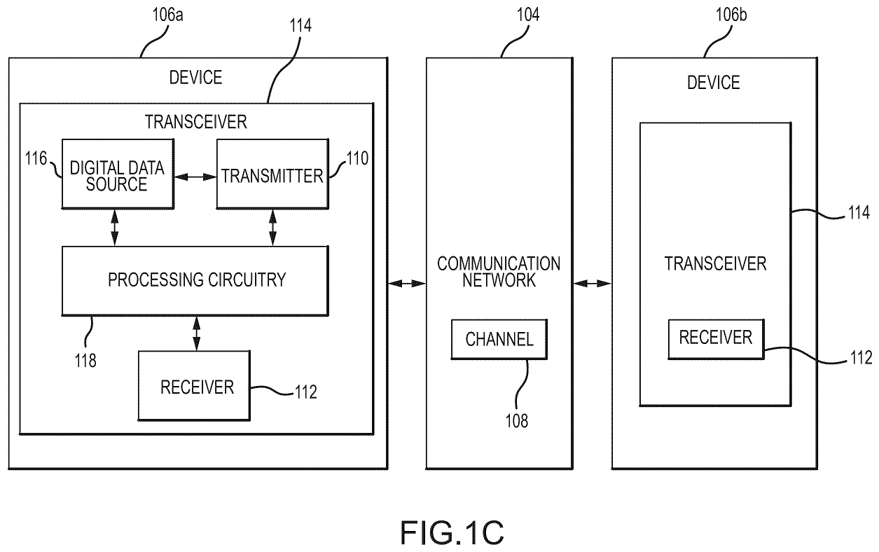

Illustrative datacenter environments and components are shown and will now be described with reference to FIGS. 1A through 17. Datacenters, high performance computing clusters, and/or the like are often formed of various computing components or networked devices, and communication networks formed of electrical and/or optical devices may be used to enable communication between the networked devices forming these implementations. As shown in FIGS. 1A, 1B, and 1C, for example, a network architecture 100 may include a datacenter 102, a communication network 104, and network device(s) 106. The network architecture 100 may illustrate a general computing architecture within which more specific systems and/or subsystems may function. Although described hereinafter with reference to a network architecture 100 and/or datacenter 102 within which the embodiments of the present disclosure may be implemented, the present disclosure contemplates that the transceiver resiliency devices and techniques described herein may be applicable to any communication implementation without limitation.

For example, the datacenter 102 may be a centralized facility designed to house computing resources and related components. The datacenter 102 may operate to support the infrastructure required for advanced computational tasks, for efficient, secure, and reliable operations. The datacenter 102 may include the building and structural components, including power supplies, cooling systems, fire suppression systems, and physical security measures that are configured to maintain optimal operating conditions and/or protect the equipment from environmental hazards and unauthorized access. An example datacenter 102 may include high-performance servers or compute nodes, often arranged in racks, such as those illustrated in FIG. 1B, and connected through high-speed networks as described herein. These servers may include processors (e.g., central processing units (CPUs), graphics processing units (GPUs), data processing units (DPUs) and/or the like), quantum processing units (QPUs), a plurality of parallel processing units (PPUs), and application-specific integrated circuits (ASICs). memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

QPUs configured to perform one or more operations associated with a quantum algorithm In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

The datacenter 102 may include high-speed network equipment, such as network switches, routers, firewalls, and/or the like to facilitate fast and secure data transmission within the datacenter 102 (e.g., between the servers or compute nodes) and between external networks. The datacenter 102 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the datacenter 102 may support high-performance computing tasks. Examples of various network topologies may include hierarchical networking topologies such as the fat tree topology, Slim Fly topology, Dragonfly topology, and/or the like. The datacenter 102 may adhere to a networking topology (e.g., a hierarchal networking topology), such as a fat tree topology, a Slim Fly topology, a Dragonfly topology, and/or the like. The datacenter 102 routes traffic amongst the network switches and servers therein, and at least one layer of the topology in the datacenter 102 is coupled to the communication network 104 to allow networking traffic to flow between the datacenter 102 and the network device(s) 106.

The communication network 104 may communicably couple the datacenter 102 with network device(s) 106 and other external devices for data exchange and connectivity. Examples of the communication network 104 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 104 to incorporate multiple network types and configurations may allow the datacenter 102 to adapt to diverse application needs, from general data communication to specialized HPC tasks. As described herein, the communication network 104 may leverage various optical components to establish communication links (e.g., communicably couple) between components in the architecture 100. As such, the communication network 104 may include various optical devices, transceivers, modules, and/or the like that are configured to generate optical signals (e.g., provide optical transmitter functionality) and/or receive optical signals (e.g., provide optical receiver functionality).

The network device(s) 106 may include a variety of computing devices capable of transmitting and receiving signals over the communication network 104. The network device(s) 106 may range from personal computing devices to complex server configurations. Examples include Personal Computers (PCs), laptops, tablets, smartphones, and servers. The network device(s) 106 may facilitate user interactions with the datacenter 102, allowing for data input, retrieval, and processing from remote locations. In addition to individual computing devices, the network device(s) 106 may also include collections of servers or additional datacenters. For instance, these could be other datacenters similar to or the same as datacenter 102. Such an interconnection may allow for the formation of a distributed computing environment for improved redundancy, load balancing, and disaster recovery capabilities. By linking multiple datacenters, the network architecture 100 may leverage geographically dispersed resources, optimizing performance and ensuring high availability.

As described herein, the datacenter 102 and/or the network device(s) 106 may include storage devices and processing circuitry for executing computing tasks, such as controlling the flow of data internally and over the communication network 104. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry 118 may comprise hardware components, such as an application-specific integrated circuit (ASIC). Other non-limiting examples of processing circuitry include Integrated Circuit (IC) chips, CPUs, GPUs, microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the datacenter 102 and network device(s) 106 may include one or more communication interfaces for facilitating wired and/or wireless communication between one another and other unillustrated elements of the network architecture 100. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 100.

Furthermore, the present disclosure contemplates that the network architecture 100 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 100 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 100.

In high-capacity datacenter networks, the communication network 104 may leverage optical transceivers that transmit and receive optical signals over optical fibers or other optical communication mediums to establish connection between devices in the architecture 100.

As shown in FIG. 1C, in one specific but non-limiting example, the communication network 104 is a network that enables data transmission between the devices 106a and 106b using data signals (e.g., digital, optical, wireless signals).

Each type of network offers specific advantages tailored to different operational requirements. For instance, an IP network or Ethernet network may provide widespread compatibility and ease of integration, supporting various protocols and applications across the datacenter 102 and the network device(s) 106 (and/or external devices). An InfiniBand network may offer high throughput and low latency, ideal for HPC environments where rapid data transfer and minimal delay are required. Fibre Channel networks may be employed for their robust performance in storage area networks (SANs), ensuring fast and reliable access to storage resources. Cellular and wireless communication networks may be used to extend connectivity to remote or mobile devices for increased flexibility and accessibility.

As noted above, the network devices 106a, 106b may include one or more of Personal Computer (PC), a laptop, a tablet, a smartphone, a server, a collection of servers, and/or any suitable computing device for sending and receiving signals over the communication network 104. In at least one example embodiment, the one or more network devices 106 correspond to another datacenter, similar to or the same as datacenter 102.

Each network device 106 may be provided with transmitter functionality 110, receiver functionality 112, and/or transceiver functionality 114. The transmitter functionality 110, receiver functionality 112, and/or transceiver functionality 114 may include hardware and/or software to support the sending and/or receiving of data across the communication network 104, through one or more communication channels 108, for example.

A network device 106 may also include a digital data source 116 and/or processing circuitry 118 to support interactions within the transceiver 114 or to support interactions between components of the transceiver 114 and other components of the device 106. For instance, the processing circuitry 118 may be included in the transceiver 114 as illustrated or may be external to the transceiver 114, without departing from the scope of the present disclosure.

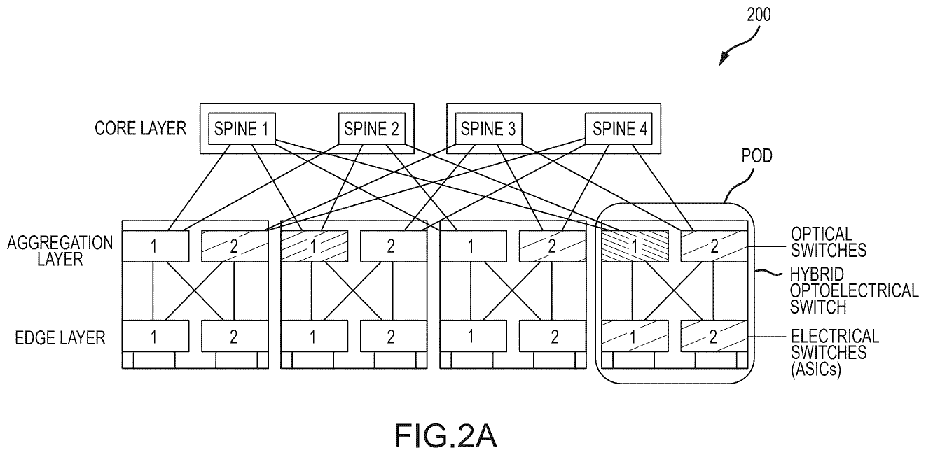

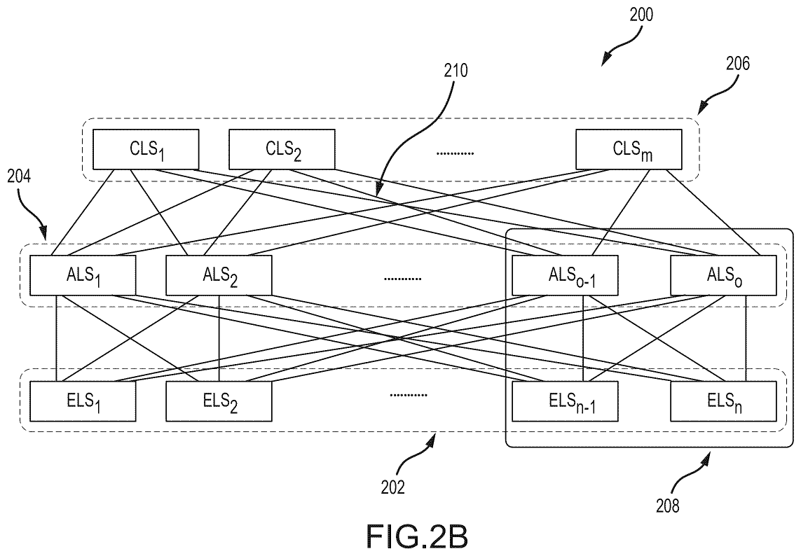

With reference now to FIGS. 2A and 2B, various topologies for use in a datacenter 102 will be described in accordance with at least some embodiments of the present disclosure. FIG. 2A illustrates a fat tree topology 200 for a datacenter 102, in accordance with embodiments of the disclosure. However, it is to be understood that the present disclosure is not limited to a fat tree topology. Other network topologies may also be contemplated within the scope of the disclosure. Examples of such alternative topologies include, but are not limited to, Slim Fly topology, which is designed to reduce the number of hops and cable lengths between nodes; Dragonfly topology, which aims to enhance network scalability and reduce latency through a hierarchical group of interconnected switches; and other hierarchical or non-hierarchical topologies that may be optimized for specific performance, scalability, or cost considerations.

The principles and innovations disclosed herein can be applied to these and other network topologies to achieve similar advantages and benefits. Any modifications, variations, or adaptations of the network topologies that fall within the spirit and scope of the present disclosure are considered to be encompassed by this disclosure. In related art systems, a fat tree topology may use the same electrical switching devices on all layers (edge, aggregation, core). For example, each switching device may be 1U switch, where 1U refers to the industry standard size for rack-mounted switch and/or server. The interconnection between switches of different layers may be accomplished with optical links using active optical cables and optical transceivers implemented in a pluggable form factor (also referred to as “pluggables”).

As shown in FIG. 2B, the fat tree topology may include three distinct layers: the edge layer 202, the aggregation layer 204, and the core layer 206. The edge layer 202, located at the bottom of the hierarchy, incorporates Top-of-Rack (ToR) switches. The edge layer 202 may serve as the initial point of aggregation for traffic originating from the servers. The servers and server racks are generally connected to the edge layer 202, although they are not illustrated in the figure. The edge layer 202 may include a plurality of switches, designated as ELS1, ELS2, . . . , ELSn, as shown in FIG. 2B. The aggregation layer 204 may be positioned above the edge layer 202 and may further consolidate traffic from multiple edge layer switches ELS1, ELS2, . . . , ELSn. The aggregation layer 204 may be composed of switches ALS1, ALS2, . . . , ALSo. The aggregation layer switches may be configured to aggregate data traffic from the edge layer 202, ensuring efficient load balancing and data flow management. At the top of the hierarchy is the core layer 206, which may provide high-speed interconnectivity and enables communication among different racks within the datacenter 102. The core layer 206 may include a series of switches labeled as CLS1, CLS2, . . . , CLSm. These core layer switches may be configured to ensure that data can traverse the network quickly and efficiently, minimizing latency and maximizing bandwidth.

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

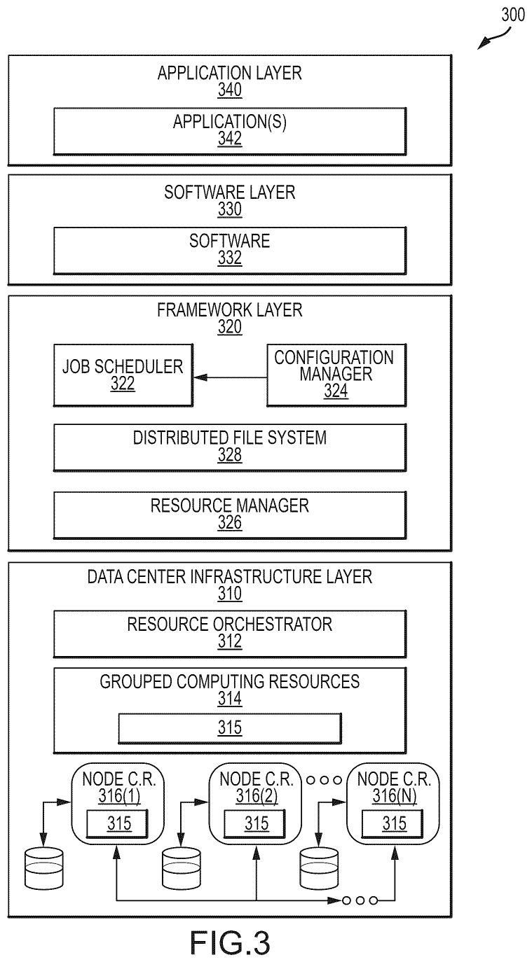

FIG. 3 illustrates additional components of an example datacenter 300 according to at least some embodiments of the present disclosure. The datacenter 300 may also include one or more modules subject to one or more cooling/thermal management features as described herein.

In at least one embodiment, datacenter 300 includes a datacenter infrastructure layer 310, a framework layer 320, a software layer 330, and an application layer 340. In at least one embodiment, the infrastructure layer 310, the framework layer 320, the software layer 330, and the application layer 340 may be partly or fully provided via computing components on server trays located in racks of the datacenter 102. This enables cooling systems of the present disclosure to direct cooling to certain ones of the computing features and the interconnect features, in an efficient and effective manner. Further, aspects of the datacenter 102, including the datacenter infrastructure layer 310, the framework layer 320, the software layer 330, and the application layer 340 may be used to support selection or design of the intermediate layers. As such, the discussion in reference to FIG. 3 may be understood to apply to the hardware and software features required to enable or support cooling functionality, for instance.

In at least one embodiment, as in FIG. 3, datacenter infrastructure layer 310 may include a resource orchestrator 312, grouped computing resources 314, and node computing resources (“node C.R.s”)316(1)-316(N), where “N” represents any whole, positive integer. In at least one embodiment, node C.R.s 316(1)-316(N) may include, but are not limited to, any number of central processing units (“CPUs”) or other processors (including accelerators, field programmable gate arrays (FPGAs), graphics processors, etc.), memory devices (such as dynamic read-only memory), storage devices (such as solid state or disk drives), network input/output (“NW I/O”) devices, network switches, virtual machines (“VMs”), power modules, and cooling modules, etc. In at least one embodiment, one or more node C.R.s from among node C.R.s 316(1)-316(N) may be a server having one or more of above-mentioned computing resources.

In at least one embodiment, grouped computing resources 314 may include separate groupings of node C.R.s housed within one or more racks (not shown), or many racks housed in datacenters at various geographical locations (also not shown). Separate groupings of node C.R.s within grouped computing resources 314 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 312 may configure or otherwise control one or more node C.R.s 316(1)-316(N) and/or grouped computing resources 314. In at least one embodiment, resource orchestrator 312 may include a software design infrastructure (“SDI”) management entity for datacenter 300. In at least one embodiment, resource orchestrator may include hardware, software or some combination thereof.

In at least one embodiment, as shown in FIG. 3, framework layer 320 includes a job scheduler 322, a configuration manager 324, a resource manager 326 and a distributed file system 328. In at least one embodiment, framework layer 320 may include a framework to support software 332 of software layer 330 and/or one or more application(s) 342 of application layer 340. In at least one embodiment, software 332 or application(s) 342 may respectively include web-based service software or applications, such as those provided by Amazon Web Services, Google Cloud and Microsoft Azure. In at least one embodiment, framework layer 320 may be, but is not limited to, a type of free and open-source software web application framework such as Apache Spark™ (hereinafter “Spark”) that may utilize distributed file system 328 for large-scale data processing (such as “big data”). In at least one embodiment, job scheduler 322 may include a Spark driver to facilitate scheduling of workloads supported by various layers of datacenter 300. In at least one embodiment, configuration manager 324 may be capable of configuring different layers such as software layer 330 and framework layer 320 including Spark and distributed file system 328 for supporting large-scale data processing. In at least one embodiment, resource manager 326 may be capable of managing clustered or grouped computing resources mapped to or allocated for support of distributed file system 328 and job scheduler 322. In at least one embodiment, clustered or grouped computing resources may include grouped computing resource 314 at datacenter infrastructure layer 310. In at least one embodiment, resource manager 326 may coordinate with resource orchestrator 312 to manage these mapped or allocated computing resources.

In at least one embodiment, software 332 included in software layer 330 may include software used by at least portions of node C.R.s 316(1)-316(N), grouped computing resources 314, and/or distributed file system 328 of framework layer 320. One or more types of software may include, but are not limited to, Internet web page search software, e-mail virus scan software, database software, and streaming video content software.

In at least one embodiment, application(s) 342 included in application layer 340 may include one or more types of applications used by at least portions of node C.R.s 316(1)-316(N), grouped computing resources 314, and/or distributed file system 328 of framework layer 320. One or more types of applications may include, but are not limited to, any number of a genomics application, a cognitive compute, and a machine learning application, including training or inferencing software, machine learning framework software (such as PyTorch, TensorFlow, Caffe, etc.) or other machine learning applications used in conjunction with one or more embodiments.

In at least one embodiment, any of configuration manager 324, resource manager 326, and resource orchestrator 312 may implement any number and type of self-modifying actions based on any amount and type of data acquired in any technically feasible fashion. In at least one embodiment, self-modifying actions may relieve a datacenter operator of datacenter 300 from making possibly bad configuration decisions and possibly avoiding underutilized and/or poor performing portions of a datacenter.

In at least one embodiment, datacenter 300 may include tools, services, software or other resources to train one or more machine learning models or predict or infer information using one or more machine learning models according to one or more embodiments described herein. In at least one embodiment, in at least one embodiment, a machine learning model may be trained by calculating weight parameters according to a neural network architecture using software and computing resources described above with respect to datacenter 300. In at least one embodiment, trained machine learning models corresponding to one or more neural networks may be used to infer or predict information using resources described above with respect to datacenter 300 by using weight parameters calculated through one or more training techniques. Deep learning may be advanced using any appropriate learning network and the computing capabilities of the datacenter 300. As such, a deep neural network (DNN), a recurrent neural network (RNN) or a convolutional neural network (CNN) may be supported either simultaneously or concurrently using the hardware in the datacenter. Once a network is trained and successfully evaluated to recognize data within a subset or a slice, for instance, the trained network can provide similar representative data for using with the collected data.

In at least one embodiment, datacenter 300 may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as pressure, flow rates, temperature, and location information, or other artificial intelligence services.

Inference and/or training logic 315 may be used to perform inferencing and/or training operations associated with one or more embodiments. In at least one embodiment, inference and/or training logic 315 may be used in system FIG. 3 for inferencing or predicting operations based, at least in part, on weight parameters calculated using neural network training operations, neural network functions and/or architectures, or neural network use cases described herein. In at least one embodiment, inference and/or training logic 315 may include, without limitation, hardware logic in which computational resources are dedicated or otherwise exclusively used in conjunction with weight values or other information corresponding to one or more layers of neurons within a neural network. In at least one embodiment, inference and/or training logic 315 may be used in conjunction with an application-specific integrated circuit (ASIC), such as Tensorflow® Processing Unit from Google, an inference processing unit (IPU) from Graphcore™, or a Nervana® (such as “Lake Crest”) processor from Intel Corp.

In at least one embodiment, inference and/or training logic 315 may be used in conjunction with central processing unit (CPU) hardware, graphics processing unit (GPU) hardware or other hardware, such as field programmable gate arrays (FPGAs). In at least one embodiment, inference and/or training logic 315 includes, without limitation, code and/or data storage modules which may be used to store code (such as graph code), weight values and/or other information, including bias values, gradient information, momentum values, and/or other parameter or hyperparameter information. In at least one embodiment, each of the code and/or data storage modules is associated with a dedicated computational resource. In at least one embodiment, the dedicated computational resource includes computational hardware that further include one or more ALUs that perform mathematical functions, such as linear algebraic functions, only on information stored in code and/or data storage modules, and results from which are stored in an activation storage module of the inference and/or training logic 315.

The switches within each layer (e.g., edge layer 202, aggregation layer 204, core layer 206) may be 1U switches. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

The terms “electrical switch,” “electrical switching ASIC,” “ASIC,” and variants thereof may used interchangeably. Although some figures illustrated herein show the electrical switches in the electrical blocks as being embodied by ASICs, example embodiments are not limited thereto, and the electrical switches may be implemented with any suitable hardware and/or software that enables routing of signals in the electrical domain. In addition, a set of optical switches at one or more levels of a hybrid optoelectrical switch may be referred to herein as an optical block while a set of electrical switches at one or more levels of a hybrid optoelectrical switch may be referred to as an electrical block.

For example, an electrical switch may include receivers that receive and convert optical signals into electrical signals for routing within the electrical switch. For example, a receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In at least one example embodiment, receiver/transmitter pairs are integrated into a single transceiver. Each electrical switch may further include internal switching circuitry for routing electrical signals within the electrical switch.

Embodiments of the present disclosure are not just limited to electrical and/or optoelectronic switches. It should be appreciated that embodiments of the present disclosure may also be utilized in quantum switches or in datacenters 102 comprising one or more quantum switches.

Data security and privacy are among the top concerns in the datacenter environment. The financial cost of a security breach can be substantial, especially when customer data is exposed. Sensitive data has historically been protected by Internet Protocol (IP) segmentation and firewalls with intrusion prevention systems that were simple and faster than encryption. However, as workloads in the corporate data enter begin to migrate to the public cloud, the need to encrypt any data traversing the network becomes foundational. Hyperscale cloud service providers are increasingly enabling encryption across their massive Data Center Interconnect (DCI) networks to meet customer expectations.

To eliminate vulnerabilities in the public cloud infrastructure all segments of the cloud datacenter network need to be fortified with encryption, including the intra-datacenter segment which poses additional challenges due to the large number of connections and smaller margins.

Overall, the security of an encryption system is limited by its weakest link. In existing systems, the known weakest link is identified as the key exchange protocol like Diffie-Hellman and Rivest-Shamir-Adleman (RSA). These systems rely on the computational complexity of the associated algorithms; it is in principle possible to hack the system provided that extremely strong processing power is available. Current systems are designed in such a way that breaking the key exchange algorithm would take unrealistic time even if the state-of-the-art processing systems are used, thus making the encryption practically unhackable. However, the advent of quantum computers is expected to disrupt this methodology since the available processing power will scale exponentially.

A quantum computer capable of implementing Shor's algorithm could factor large integers exponentially faster than a classical computer, rendering common asymmetric public key encryption protocols such as RSA ineffective. Such a quantum computer can crack public encryption protocols much faster than a classical computer, rendering them unsecure. New “quantum secure” key exchange solutions are required, and ongoing research is investigating software and hardware approaches. On the software side, Post Quantum Cryptography (PQC) is focusing on algorithms that are quantum-resistant (e.g., encryption methods based on math that a quantum computer is not advantaged in computing). On the hardware side, QKD facilitates key exchange by exchanging photons which, by the principles of quantum physics, will be perturbed in a detectable way if an eavesdropper is present. Consensus is that for highest security a hybrid approach should be pursued, combining PQC with QKD.

A pervasive and future-proof solution for intra-datacenter security combining PQC and QKD faces several challenges, primarily related to the hardware nature and current implementation particularities of QKD.

QKD equipment is commercially available and is finding application in use cases where particular point-to-point links need to be secured, such as in inter-datacenter connections. The hardware essence of QKD requires changes to the overall network design and infrastructure. Typically, QKD equipment is added alongside existing network equipment to facilitate key exchange in select connections which are considered non-trusted. For example, in the DCI use case, each individual datacenter network is considered a trusted zone and only the connections between datacenters are enhanced by QKD. Hence, only the DCI-facing ports of the relevant network infrastructure are combined with the QKD equipment and are encrypted using QKD keys. Current QKD equipment is considerably bulky (e.g., a rack mountable form factor with several rack units of height); however, as only a few units are needed, integration is feasible without significant implications to the data center operator. However, when migrating to an intra-datacenter installation following the zero-trust concept where all links have to be secured, the number of QKD connections rises dramatically. The current form factor of QKD equipment inhibits realistic deployment inside the datacenter as it would consume the majority of each rack's volume and would degrade computational density. It is expected that new technologies (such as photonic integrated circuits) will enable the future miniaturization of QKD equipment.

A switch, whether electric, optoelectronic, and/or quantum, may include input circuit(s) and output circuit(s), linked by switching core. In some embodiments, a switch may include multiple inputs and outputs.

A number of architectures of this type have been proposed, including “Next Generation I/O” (NGIO) and “Future I/O” (FIO), culminating in the “InfiniBand” architecture, which has been advanced by a consortium led by a group of industry leaders (including Intel, Sun, Hewlett Packard, IBM, Compaq, Dell and Microsoft). Storage Area Networks (SAN) provide a similar, packetized, serial approach to high-speed storage access, which can also be implemented using an InfiniBand fabric.

Communications between a parallel bus and a packet network generally require a communications interface, to convert bus cycles into appropriate packets and vice versa. For example, a host channel adapter or target channel adapter can be used to link a parallel bus, such as the PCI bus, to the InfiniBand fabric. When the adapter receives data from a device on the PCI bus, it inserts the data in the payload of an InfiniBand packet, and then adds an appropriate header and error checking code, such as a cyclic redundancy check (CRC) code, as required for network transmission. The InfiniBand packet header includes a routing header and a transport header. The routing header contains information at the data link protocol level, including fields required for routing the packet within and between fabric subnets. The transport header contains higher-level, end-to-end transport protocol information. Similar headers are used in other types of packet networks known in the art, such as Internet Protocol (IP) networks.

In at least one embodiment, aspects of the present disclosure may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (DSP), an SoC, network computers (“NetPCs”), set-top boxes, network hubs, wide area network (“WAN”) switches, or any other system that may perform one or more instructions. In an embodiment, a computer system having one or more aspects of the present disclosure may be used in devices such as graphics processing units (GPUs), network adapters, central processing units, and network devices such as switches (e.g., a high-speed direct GPU-to-GPU interconnect such as the NVIDIA GH100 NVLINK or the NVIDIA Quantum 2 64 Ports InfiniBand NDR Switch).

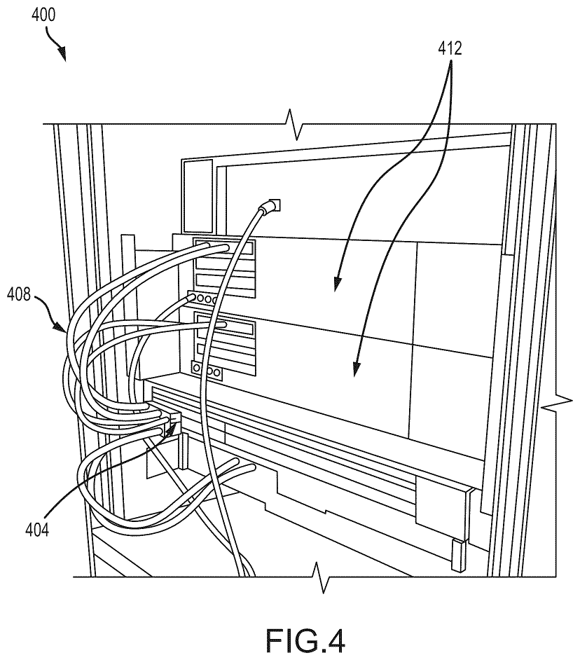

FIG. 4 illustrates an example datacenter rack 400, or cabinet that is designed to house servers, networking devices, modules, and other datacenter 102 computing equipment and used in conjunction with optical fibers 408.

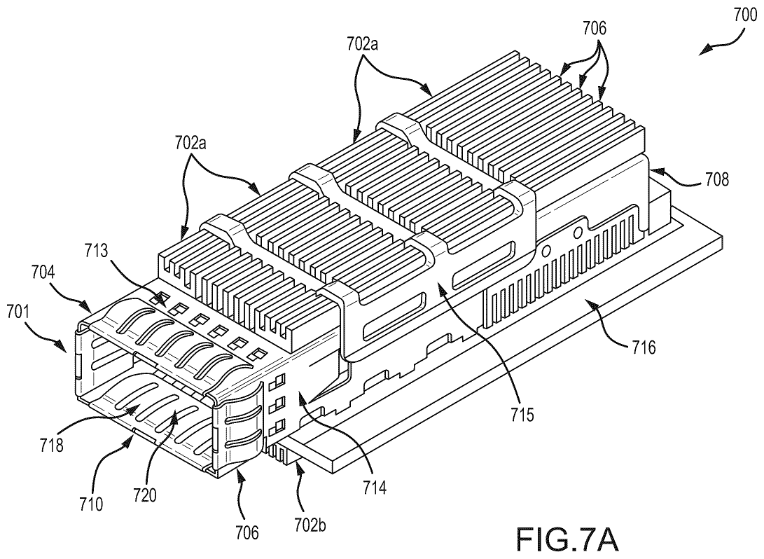

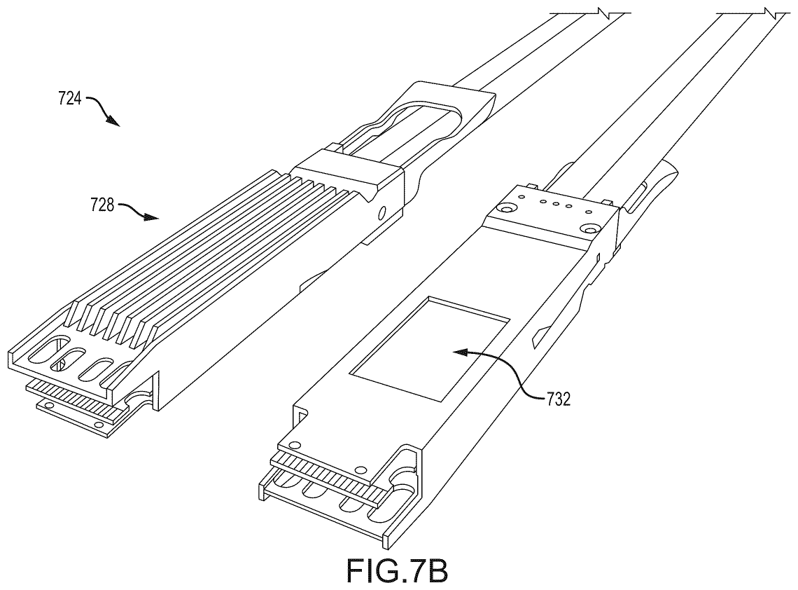

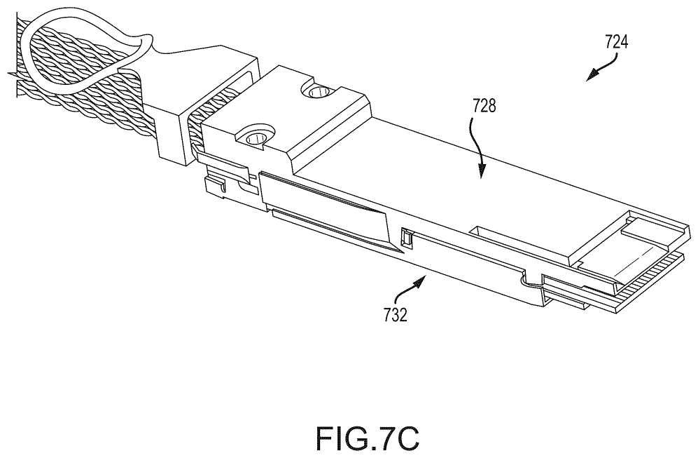

Accordingly, various different types of cable connectors, such as those illustrated in FIGS. 7B and/or 7C, also exist for enabling transmission of signals (optical and/or electrical) between switch modules and other equipment in a datacenter. For example, OSFP connectors and cables, as well as other forms of connectors such as QSFP, Small Form Pluggable (SFP), and C-Form-factor Pluggable (CFP) connectors provide high-speed information operations interface interconnects. Regardless of the type of cable connectors, these transceivers may interface a switch system board, such as a motherboard in a switch system, to a fiber optic or copper networking cable, such as by making connections between switch modules 412 as shown in FIG. 4.

With continued reference to FIG. 4, for example, a switch module 412 (or other interconnect module), which may house an application-specific integrated circuit (ASIC) as well as other internal components (not visible), is typically incorporated into a datacenter 102 via connections to other switch systems, servers, racks, and network components. A switch module 412 may, for example, interact with other components of the datacenter 102 via external optical cables 408 and possible transceiver systems housed in the end of an optical cable 408. These optical cables 408 and transceivers may allow connections between a switch module 412 and the other components of the datacenter 102 via cage receptacle assemblies 404.

The switch modules 412 may be configured to be received by a datacenter rack 400 and may be configured to allow for the conversion between optical signals and electrical signals. For example, optical cables 408 may carry optical signals as inputs to the switch module 412. The optical signals may be converted to electrical signals via an opto-electronic transceiver assembly, which may form part of the optical cable 408 in cases in which the optical cable 408 is an Active Optical Cable (AOC), such as a cable that includes a OSFP connector that is received by a port of a switch module 412. In other cases, the optical cable 408 may be passive, and the switch module 412 may include opto-electronic components that convert between optical signals and electrical signals. The electrical signals may then be processed by the switch module 412 and/or routed to other computing devices, such as servers and devices on other racks or at other datacenters via other components and cables (not shown). In addition, electrical signals received from other networking devices (e.g., from other datacenters, racks, etc.) may be processed by the switch module 412 and then converted into corresponding optical signals to be transmitted via the optical cables 408, going the opposite direction.

The transmission of data as electrical signals and the conversion between optical signals and electrical signals (e.g., via an AOC and associated transceiver system or AOM) often results in the generation of heat by the components of the datacenter rack 400. As can be appreciated, higher temperatures associated with such heat emissions can correspond to the increased likelihood of failure of electrical components and/or changes in the electrical and/or optical operating parameters of the components resulting in interference with the corresponding electrical and/or optical signals. Additionally, localization or concentration of higher temperatures in electrical components (e.g., the bottom surface of the AOC, AOM, or pluggable cable connector) can result in a further increase in the likelihood of failure of electrical components located near the area of heat concentration.

Accordingly, embodiments of the disclosure described herein provide a cage receptacle assembly that is configured to provide increased thermal efficiency by allowing the heat dissipation units to be independently adjustable relative to the cage body (e.g., “floating”), so that their spatial position and orientation state is aligned with the position and orientation of the respective top or bottom surfaces of the plugged transceiver to achieve effective heat transfer from the transceiver surfaces to the heat dissipation elements. In embodiments, the contact area between the transceiver and heat dissipation unit(s) is enlarged to allow for more surface area of the transceiver contacting the heat dissipation unit(s) to distribute heat more evenly and/or to more effectively dissipate the heat to the surrounding environment to maintain lower temperatures in the components.

It should further be noted that a cable 408 (and similarly the other active optical cables described herein) and connectors may be designed to comply with any applicable standard, for example Ethernet and InfiniBand standards, such as Ethernet variants 200GBASE-FR4, 400GBASE-FR4, and 100GBASE-LR4 to support four wavelengths. Connections between the cable 408 and the switch module 412 may be facilitated by one or more of a transceiver module and a cage receptacle assembly.

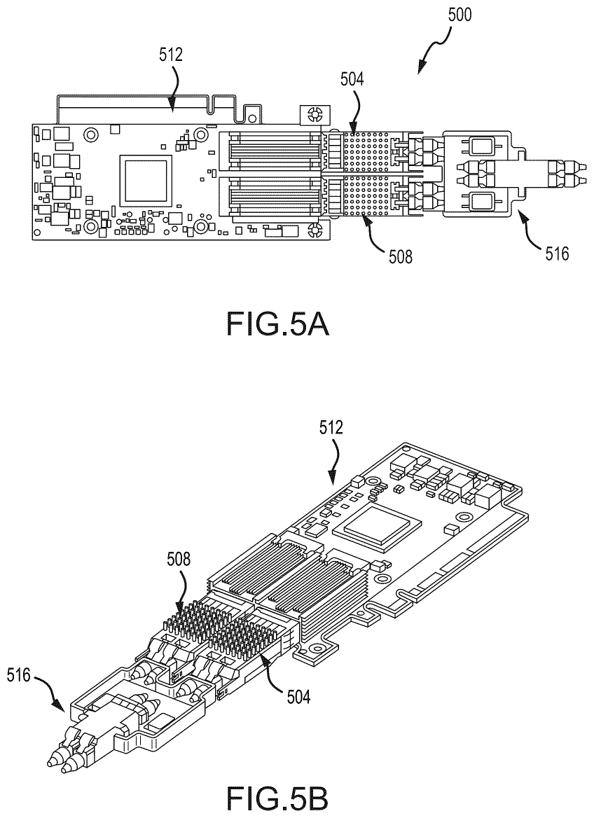

FIGS. 5A and 5B illustrate a top view and a perspective view, respectively, of a transceiver module operatively coupled to a network adapter, in the present example a Network Interface Controller (NIC) 500, in accordance with an embodiment of the disclosure. As shown in FIGS. 5A and 5B, the transceiver module may include a first optical module 504, a second optical module 508, an adapter 516, and a dual-port NIC 512 of a server. Both the first optical module 504 and the second optical module 508 may be dual-fiber transceivers that are configured for duplex communication that allows the source (e.g., server) to communicate with the target (e.g., leaf switch) in both directions. The adapter 516 may be a ganged physical component configured to link the first optical module 504 and the second optical module 508 for the purpose of transmitting and receiving data to and from a switch, such as a leaf switch.

In some embodiments, the adapter 516 may be configured to operate in two configurations, such as a first configuration and a second configuration. In one aspect, the first configuration may be a default configuration of operation, where the first optical module 504 may be operationally active. The second configuration may be a contingent configuration that is implemented when the first optical module 504 operationally fails. When such a failure is detected, the second optical module 508, which is otherwise operationally inactive or idle, may be engaged become operationally active and handle all network traffic that was initially handled by the first optical module 504.

In some embodiments, the transceiver module 500 may be configured to operate in a leaf-spine architecture. A leaf-spine architecture is a datacenter 102 topology that may include two or more switching layers (e.g., a spine layer and a leaf layer). The leaf layer may include access switches (leaf switches) that aggregate traffic from servers and connect directly into the spine or network core. Spine switches interconnect all leaf switches in a full-mesh topology between access switches in the leaf layer and the servers from which the access switches aggregate traffic.

As such, in one embodiment, to ensure reliable operation of downlinks, the transceiver module 500 may be configured to operate between the server and the leaf layer. In particular, as shown in FIGS. 5A and 5B, the adapter 516 may be operatively coupled to the first optical module 504 and the second optical module 508, while the first optical module 504 and the second optical module 508 may be operatively coupled to a dual-port NIC 512 of a server.

In embodiments, transceiver module 500 may comprise one or more processing circuits, as detailed above; the processing circuits may comprise FW, that is loaded according to the techniques described above.

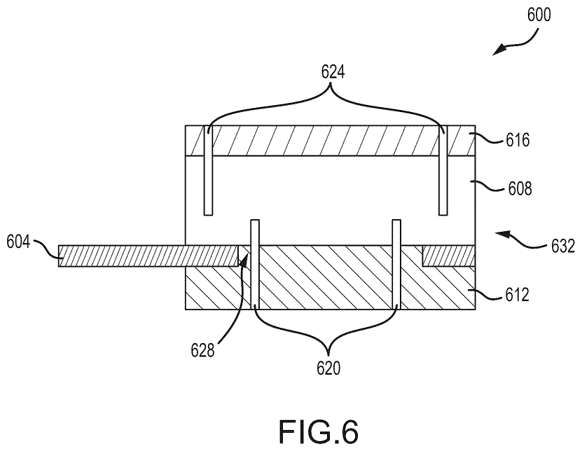

With reference now to FIG. 6, a block diagram of an illustrative cage receptacle assembly 600 will be described in accordance with at least some embodiments of the present disclosure. The cage receptacle assembly 600 may include a PCB 604 on which a cage body 608 is mounted. In some embodiments, the cage body 608 is mounted to a first side of the PCB 604 (e.g., a top side of the PCB 604). A first heat dissipation unit 612 may be positioned proximate to a first side of the cage body 608 (e.g., a bottom side of the cage body 608) and may be provided to cool a bottom side of the cage body 608. In some embodiments, the first heat dissipation unit 612 is positioned proximate to a second side of the PCB 604 (e.g., a bottom side of the PCB 604) and is in thermal communication with the cage body 608 through a hole 628 or via provided in the PCB 604.

In some embodiments, a portion of the first heat dissipation unit 612 may extend through the hole 628 of the PCB 604 and may at least partially contact a bottom surface of the cage body 608. Direct contact between the first heat dissipation unit 612 and the cage body 608 may enable the first heat dissipation unit 612 to directly transfer heat away from the cage body 608. An additional benefit of providing the first heat dissipation unit 612 through the hole 628 in the PCB 604 is that the first heat dissipation unit 612 may transfer heat away from the PCB 604 as well. The first heat dissipation unit 612 may also be referred to as a heat sink or a bottom side heat sink without departing from the scope of the present disclosure.

The cage receptacle assembly 600 is shown to further include a second heat dissipation unit 616. The second heat dissipation unit 616 may be positioned proximate to a second side of the cage body 608 (e.g., a top side of the cage body 608). In some embodiments, the second heat dissipation unit 616 may directly contact at least a portion of the top side of the cage body 608. In such a configuration, the second heat dissipation unit 616 may be configured to transfer heat away from the cage body 608. By providing a first heat dissipation unit 612 and second heat dissipation unit 616 on opposing sides of the cage body 608, heat generated within the cage body 608 may be efficiently transferred away from all sides of the cage body 608. The second heat dissipation unit 616 may also be referred to as a heat sink or a top side heat sink without departing from the scope of the present disclosure.

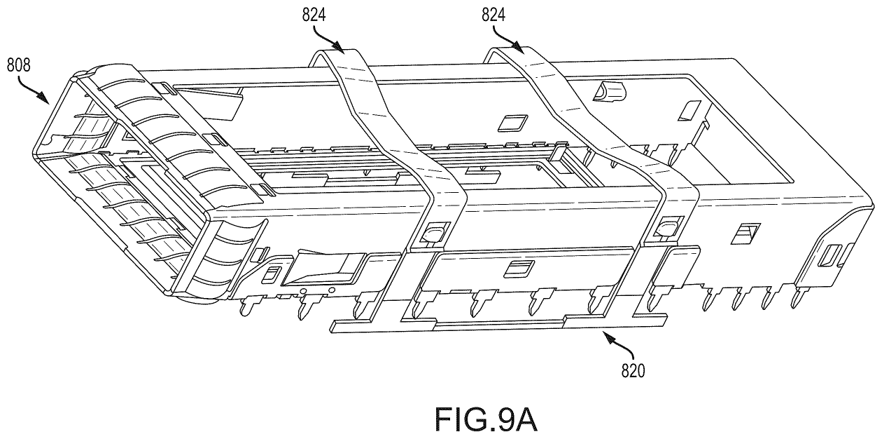

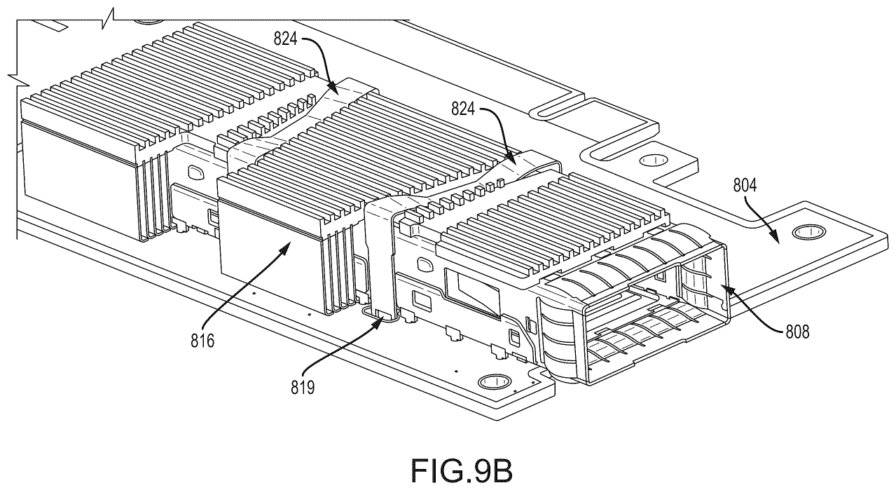

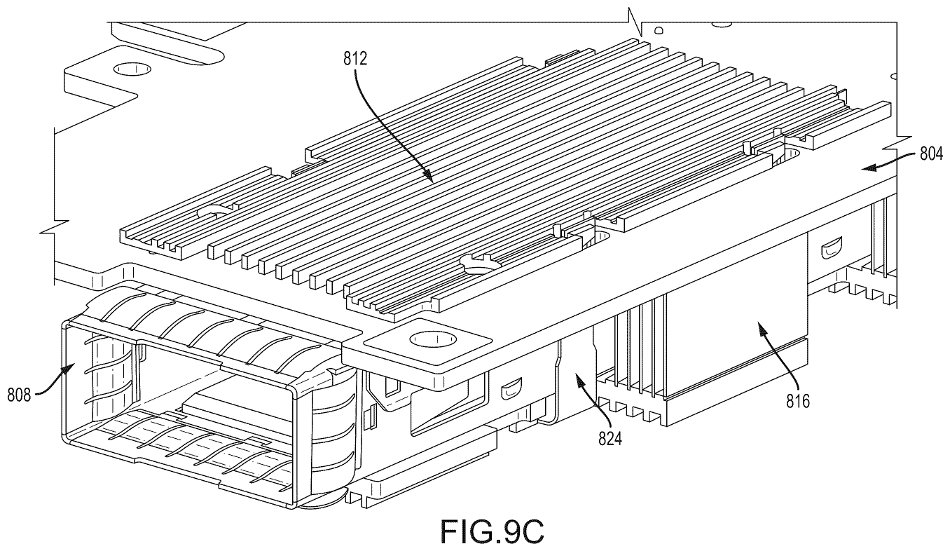

FIG. 6 further illustrates components of a securing element that can be used to secure the dissipation units 612, 616 to the cage body 608, either directly or via the PCB 604. In some embodiments, a first portion of the securing element 620 is used to secure the first heat dissipation unit 612 to the PCB 604 and/or the cage body 608. The first portion of a securing element 620 may wrap around at least a portion of the first heat dissipation unit as illustrated further below with respect to FIG. 9A. In some embodiments, a second portion of the securing element 624 is used to secure the second heat dissipation unit 616 to the PCB 604 and/or the cage body 608. While illustrated as separate elements, it should be appreciated that the first portion of the securing element 620 and the second portion of the securing element 624 may cooperate with one another (e.g., connect together) to hold the other components of the cage receptacle assembly 600 together. As will be described herein, the portions of the securing element 620, 624 may include one or more of a force element, a retention mechanism, a spring, a pin, or the like.

In some embodiments, the first heat dissipation unit 612 and/or the second heat dissipation unit 616 may be releasably connected to the PCB 604 and/or cage body 608. In some embodiments, the first heat dissipation unit 612 and/or the second heat dissipation unit 616 may be connected to the other components of the cage receptacle assembly 600 in such a way that one or both heat dissipation unit 612, 616 is allowed to float relative to the cage body 608 or the cage body 608. In other words, the heat dissipation units 612, 616 may be independently adjustable relative to the cage body 608 (e.g., “floating”), so that their respective spatial position and orientation state is derived from the position and orientation of the respective top or bottom surfaces of cable inserted into the cage body 608. Said another way, when an end of a cable (e.g., a cable connector) is inserted into an opening of the cage body 608 provided on a front face 632 of the cage body 608, one or both of the heat dissipation units 612, 616 may float or adjust their relative position to accommodate a top and/or bottom surface of the cable connector inserted into the cage body 608. In other words, the cable connector, when inserted into the cage body 608, may move one or both of the heat dissipation units 612, 616.

The cage body 608 may be constructed of sheet metal or some other thermally-conductive material. In some embodiments, the cage body 608 is formed from one or more pieces of sheet metal that are bent/folded and/or cut in appropriate locations to create the structure of the cage body 608.

With reference now to FIGS. 7A-10, additional details of possible cage receptacle assemblies and the cable connectors that may be inserted therein will be described in accordance with at least some embodiments of the present disclosure.

FIG. 7A illustrates one such example of a cage receptacle assembly 700. The cage assembly receptacle assembly 700 is shown to include a cage body 701. The cage body 701 may correspond to an example of a cage body 608.

The cage body 701 of the cage receptacle assembly 700 may be defined by a top cage member 704 that defines a top portion 713 and two side portions 714 that extend between the top portion 713 of the top cage member 704 to a bottom cage member 706. The top cage member 704 may be configured to attach to the bottom cage member 706 to form the cage body 701. The cage body 701 of the cage receptacle assembly 700 may be configured to at least partially receive a cable connector 724 as illustrated in FIGS. 7B or 7C (e.g., a QSFP cable and/or connector) such that a top surface 728 of the cable connector 724 is disposed proximate the top cage member 704 and a bottom surface 732 of the cable connector 724 is disposed proximate the bottom cage member 706.

The cage receptacle assembly 700 may also define a first end 710 and a second end 708 opposite the first end 710, where the first end 710 is configured to receive a cable connector 724. For example, the first end 710 of the cage receptacle assembly 700 may be defined such that at least a portion of the cable connector 724 may be inserted into the cage receptacle assembly 700, or otherwise brought into engagement or contact with an inner surface 718 of cage body 701 via the first end 710. The first end 710 may be configured to receive a cable connector 724 of any suitable dimension or of any suitable type (e.g., AOC, Ethernet, Direct Attach Copper, etc.) such that the top cage member 704 is located proximate to the top surface 728 of the cable connector 724 and the bottom cage member 706 is located proximate to the bottom surface 732 of the cable connector 724. As a non-limiting example, the first end 710 may be configured to receive a cable connector 724 corresponding to a QSFP cable connector, such that the QSFP is secured to the cage receptacle assembly 700 by engaging at least a part of the inner surface 718 of the cage body 701 via the first end 710.

The cage body 701 may further define a second end 708 opposite the first end 710, where the second end 708 is configured to be received by a module for enabling signals to pass between the cable connector 724 and a module. The cage receptacle assembly 700 may be configured to engage, or be secured to, a module (e.g., switch module 412). The cage receptacle assembly 700 may be configured such that the second end 708 defines at least one extension capable of being received by a datacenter switch module 412 (e.g., male to female connection). As discussed above, the opening 720 defined by the cage body 701 of the cage receptacle assembly 700 may be such that a cable connector 724 may extend through the cage body 701 of the cage receptacle assembly 700. Specifically, the cable connector 724 may be configured (e.g., sized and shaped) such that upon engagement of the second end 708 of the cage receptacle assembly 700 with the module, the cable connector 724 may also engage the switch module 412 such that signals may be transmitted between the cable connector 724 and switch module 412.

By way of a more particular example, a cable connector 724 may be received by the cage receptacle assembly 700 such that at least a portion of the cable connector 724 is supported and/or surrounded by the cage body 701 of the cage receptacle assembly 700. Illustratively, connector 724 (e.g., the end of a cable configured to engage a module and allow electrical communication therethrough) may be positioned such that when the cage receptacle assembly 700 engages the module 412, the cable connector 724 engages a corresponding port of the system to allow signals (e.g., electrical signals, optical signals, or the like) to travel between the cable connector 724 and the module 412.

The cage receptacle assembly 700 may further include a first dissipation unit 702a and a second heat dissipation unit 702b. One or both of the heat dissipation units 702a, 702b may be secured to the cage body 701 via a clip 715, which may also be referred to as a spring or securement mechanism 715. While the cage body 701 is mounted on a top side of a PCB 716, one of the heat dissipation units (e.g., the second heat dissipation unit 702b) may be mounted on a bottom side of the PCB 716.

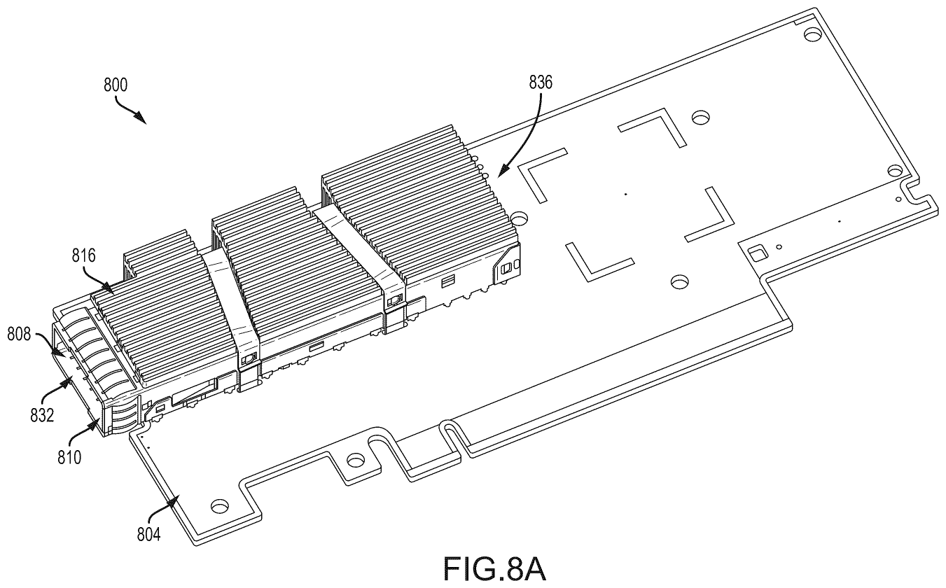

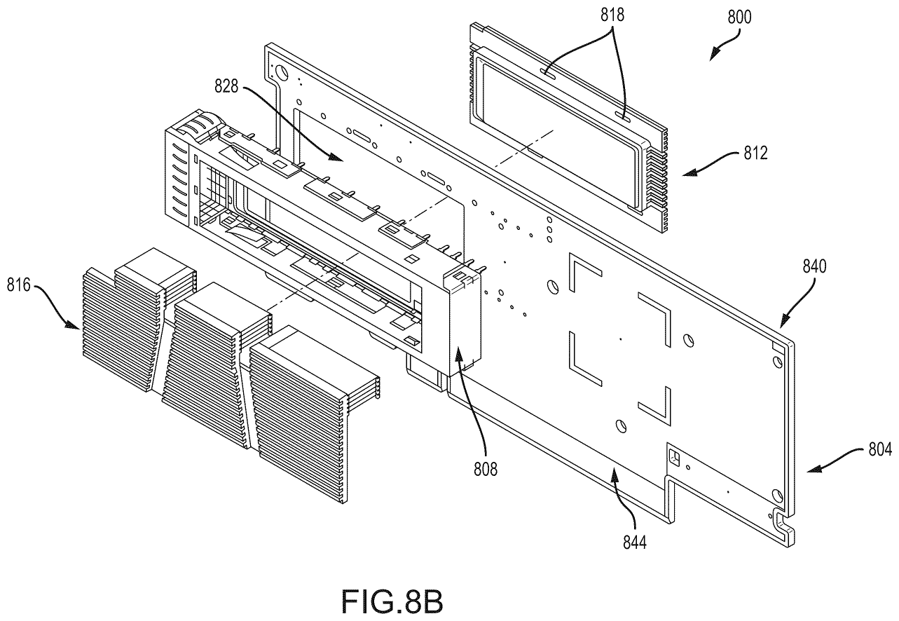

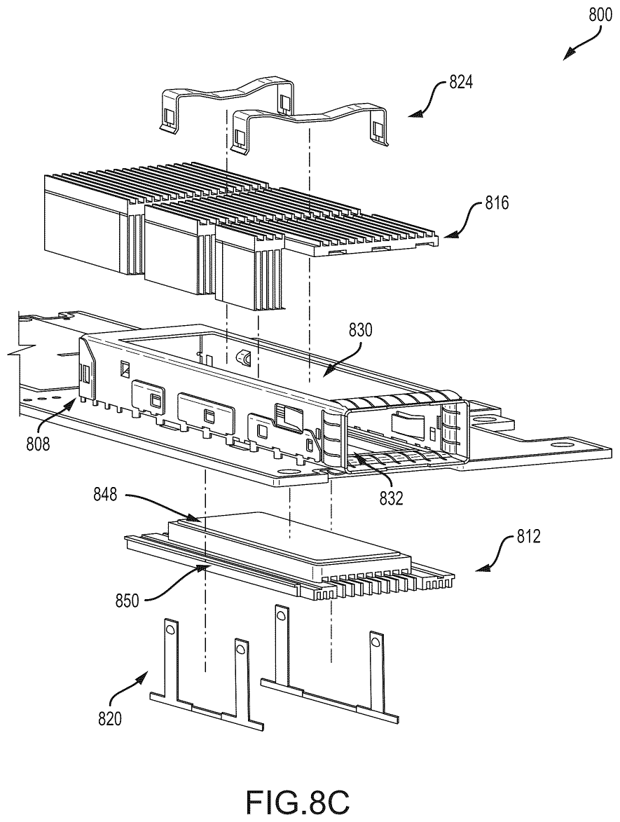

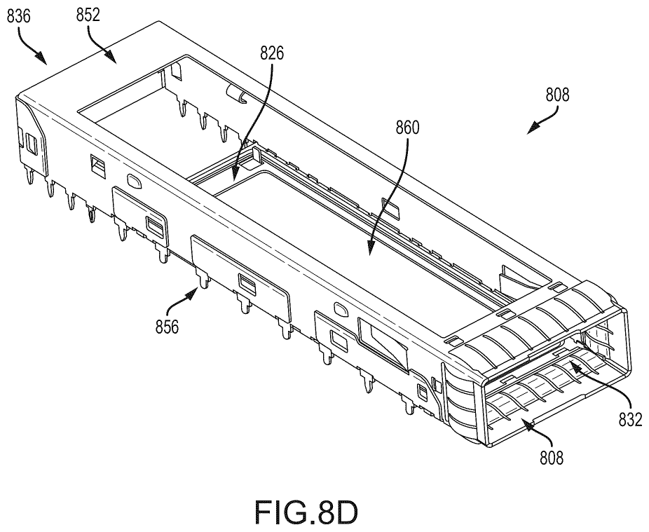

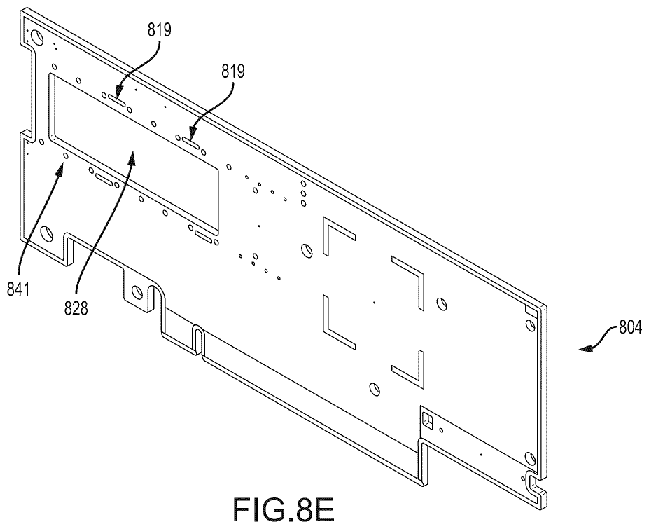

FIGS. 8A-E illustrate various views of another cage receptable assembly 800 and various components in accordance with the present disclosure. The cage receptable assembly 800 may be another example of a cage receptacle assembly 600.

FIG. 8A illustrates an assembled cage receptable assembly 800. As shown, the cage receptable assembly 800 may include a top heat dissipation unit in the form of a second heat dissipation unit 816. The first heat dissipation unit 812, which may also be referred to as a bottom heat dissipation unit, is shown in FIGS. 8B and 8C. The first heat dissipation unit 816 may be configured to cover some or all of the top 852 of the cage body 808. The first heat dissipation unit 812 may correspond to an example of the first heat dissipation unit 612 and the second heat dissipation unit 816 may correspond to an example of the second heat dissipation unit 616.

The bottom 826 and/or top 852 of the cage body 808 may be attached to a PCB 804. The cage body 808 may correspond to an example of a cage body 608 and the PCB 804 may correspond to an example of PCB 604. In some embodiments the cage body 608 may be created from a single sheet of metal that has been cut and/or folded into a form of the cage body 608.

Both of the heat dissipation units 812, 816 may be referred to as “floating,” or independently adjustable to a cable connector geometry for improved heat dissipation. The cage receptable assembly 800 is shown to include a standard cage receptacle footprint, which enables connecting a standard cage receptacle to the same PCB for low power/high LFM applications. Additionally, the cage receptacle assembly 800 is compact, enabling tight placement between two adjacent cage receptacle assemblies. For example, placement of two QSFP cage receptacle assemblies on the west boarder of a HHHL PCIe card.

As would be understood by one of ordinary skill in the art in light of the present disclosure, the PCB 804 may include various optical and/or electrical components. In some embodiments, the PCB 804 may include one or more transducers (e.g., vertical-cavity surface-emitting lasers (“VCSELs”)) configured to convert electrical signals into optical signals, and/or one or more photodiodes configured to convert optical signals into electrical signals. As shown in FIGS. 8B, 8C, and 8D, the PCB 804 may include a hole 828 or opening that substantially aligns with a hole 860 or opening defined in a bottom surface of the cage body 808. The second heat dissipation unit 812, may be aligned with the hole 828 of the PCB 804 as well the hole 860 defined in the bottom 826 of the cage body 808. At least a portion of the first heat dissipation unit 812 may also extend at least partially through both the hole 828 and the hole 860 to contact a cable connector 724 inserted into a first end 832 of the cage body 808.

For example, the cage body 808 may be defined such that at least a portion of the cable connector 724 may be inserted into the cage body 808, or otherwise brought into engagement or contact with an inner surface 810 of cage body 808. The cage body 808 may be configured to receive a cable connector 724 of any suitable dimension or of any suitable type (e.g., AOC, Ethernet, Direct Attach Copper, etc.). By way of example, the cage body 808 may be configured to receive a cable connector 724 corresponding to an OSFP cable connector, such that the OSFP cable connector is secured to the cage receptacle assembly 800 by engaging at least a part of the inner surface 810 of the cage body 808.

The cage receptacle assembly 800 may further define a second end 836 opposite to the first end 832 receiving the cable connector. In some embodiments, the second end 836 is configured to be received by a module for enabling signals to pass between the cable connector 724 and a module 412. The cage receptacle assembly 800 may be configured to engage, or be secured to, a module (e.g., switch module 412). The cage body 808 may be configured such that the second end 836 defines at least one extension capable of being received by a datacenter component (e.g., male to female connection). Specifically, but without limitation, the active end of the cable connector 724 may be configured (e.g., sized and shaped) such that upon engagement of the second end 836 of the cage receptacle assembly 800 with the module 412, the active end of the cable connector 724 may also engage the module 412 such that signals may be transmitted between the cable connector 724 and module 412.

The second heat dissipation unit 816 is configured to cover (partially or completely) the cage body 808 and attach to a second side 844 (e.g., top side) of the PCB 804. In such a configuration, the second heat dissipation unit 816 may be referred to as a top heat dissipation unit. The second heat dissipation unit 816 may be configured to at least partially contact a top surface 728 of a cable connector 724 when a cable connector 724 is inserted into the cage body 808. In some embodiments, the second heat dissipation unit 816 may contact the cable connector 724 through a top opening 830 provided in a top 852 of the cage body 808. The second heat dissipation unit 816 may comprise a finned structure to increase a surface area thereof and to help dissipate heat away from the cage body 808. As used herein, a finned structure may correspond to a portion or collection of portions of a heat dissipation unit that includes an extended surface (e.g., a fin) that protrudes from the base of the heat sink. As can be appreciated, a finned structure may significantly increase a surface area of the heat dissipation unit allowing for more efficient heat dissipation to the surrounding environment through convection. In this sense, the finned structure of a head dissipation unit may provide small fins or wings that maximize heat transfer by exposing a larger area to the surrounding environment.

The first heat dissipation unit 812 may be disposed on a first side 840 (e.g., bottom side) of the PCB 804. In some embodiments, the first heat dissipation unit 812 may include a first portion 848 and a second portion 850. The first portion 848 of the first heat dissipation unit 812 may correspond to the portion of the first heat dissipation unit 812 that extends through the hole 828 of the PCB 804 and a bottom opening 860 of the cage body 808. At least one face of the first portion 848 of the first heat dissipation unit 812 may directly contact a cable connector 724 inserted into the cage body 808. In embodiments, the first portion 848 has a smaller surface area than the second portion 850. When disposed on a first side 840 of the PCB 804, the first portion 848 of the first heat dissipation unit 812 is in thermal communication with at least one of the cage body 808 and the bottom surface 732 of the cable connector 724. The second portion 850 may comprise a finned structure having an enhanced surface area to facilitate the transfer of heat away from the cage body 808.

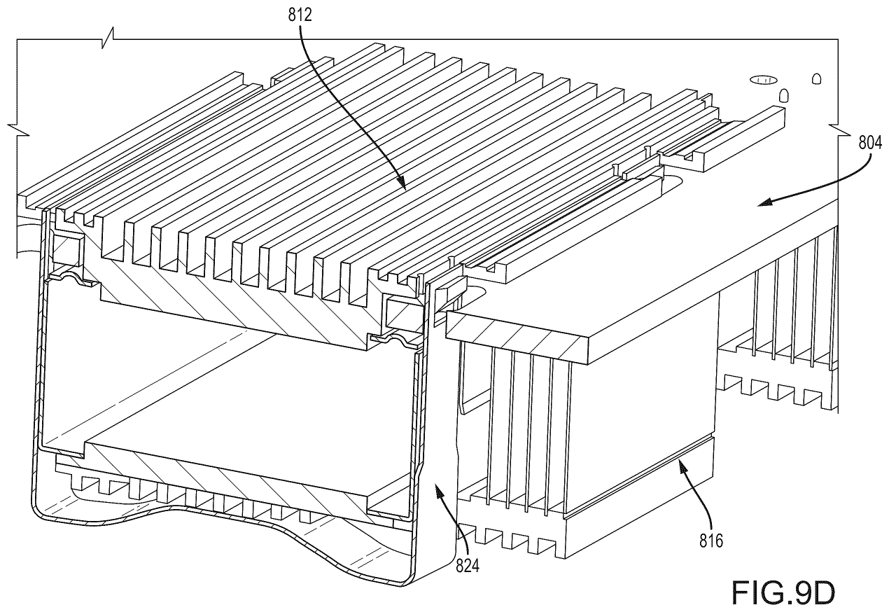

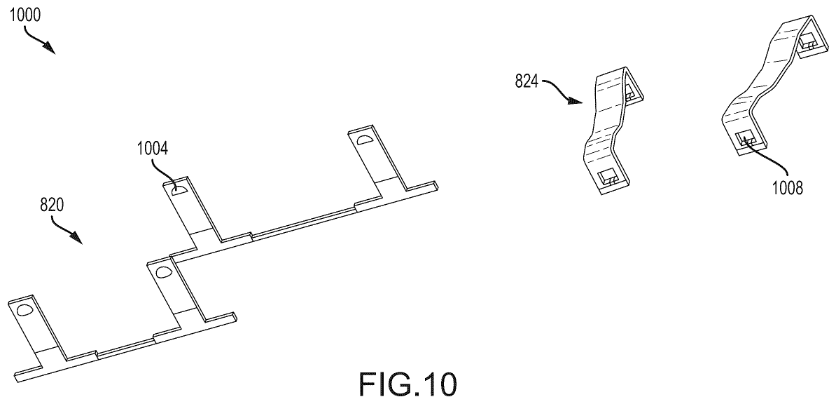

In embodiments, legs or pins of the first portion of the securing element 820 (shown in more detail in FIGS. 9A-10) may go through the holes 818 in the first heat dissipation unit 812, and then through the holes 819 in the PCB 804 to attach to a second portion of a securing element 824. The second portion of the securing element 824 may also wrap around some or all of the second heat dissipation unit 816 such that forces exerted by the securing elements 820, 824 collectively secure the first heat dissipation unit 812 and the second heat dissipation unit 816 together, while also allowing such heat dissipation units 812, 816 to be independently adjustable to a cable connector geometry for improved heat dissipation. The first portion of the securing element 820 and the second portion of the securing element 824 may be referred to as securing elements, retention mechanisms, or the like. The securing elements 820, 824 may, in some embodiments, secure the heat dissipation units 812, 816 from both sides of the PCB 804 with a spring-like or flexible retention force. In this way, the securing elements 820, 824 may apply retention forces that flexibly hold or retain the heat dissipation units 812, 816 relative to the cage body 808. In some embodiments, the securing elements 820, 824 may flexibly hold (e.g., retain with a degree of flexibility) the heat dissipation units 812, 816 such that movement of the heat dissipation units 812, 816 is allowable when a cable connector is inserted into the cage body 808 (e.g., to accommodate the cable connector in the cage body 808). When flexibly holding the heat dissipation units 812, 816, the securing elements 820, 824 may apply a certain amount of retention force that allows the heat dissipation units 812, 816 to move in response to having a larger force applied thereto by the cable connector being positioned within the cage body 808 and contacting the heat dissipation units 812, 816.

FIG. 8C illustrates an exploded view of the cage receptable assembly 800 according to embodiments of the present disclosure. As noted above, the first portion of the securing element 820 is shown to hold the first heat dissipation unit 812 in place, by passing through the first heat dissipation unit 812 via holes 818 and by passing through PCB 804 via holes 819. The first portion of the securing element 820 engages the second portion of the securing element 824.

The second portion of the securing element 824 may wrap around the second heat dissipation unit 816, which is disposed above the top 852 of the cage body 808 as illustrated further below with respect to FIG. 9A. In embodiments, the positioning of the different portions of the securing elements may be reversed (e.g., the first portion of the securing element 820 may wrap around the second heat dissipation unit 816 while the second portion of the securing element 824 may wrap around the first heat dissipation unit 812).

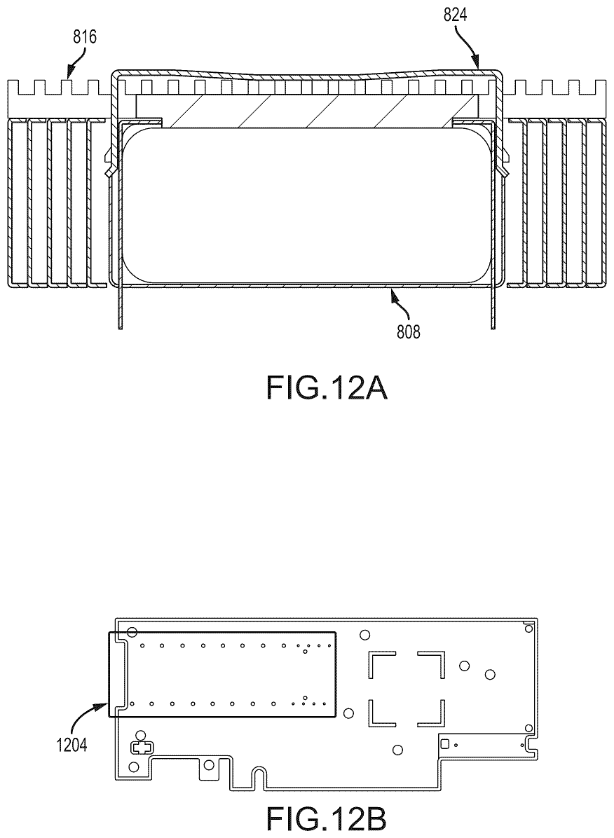

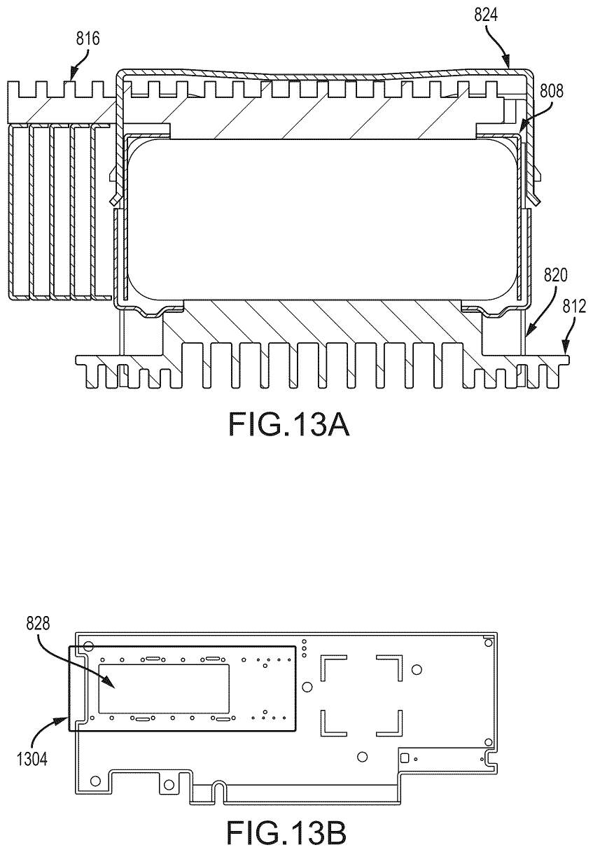

The heat dissipation units 812, 816 may be configured to facilitate the transfer of heat from a cable connector 724 that is at least partially received within the cage receptacle assembly 800. The heat dissipation units 812, 816 may include, be constructed from, or be covered with a conductive material (e.g., thermal interface material). In embodiments, the pins 856 on the cage body 808 insert into the holes 841 in the PCB 804 to attach the cage body 808 to the PCB 804. Use of the pins 856 may help to maintain a desired position of the cage body 808 on the PCB 804. For instance, as can be seen in FIGS. 12A, 12B, 13A, and/or 13B, the cage body 808 may be configured to rest within a predetermined area 1204 and/or 1304 on the PCB 804. In the embodiment of FIGS. 12A and 12B, the predetermined area 1204 on the PCB 804 may not include a hole or opening therein. In the embodiment of FIGS. 13A and 13B, the predetermined area 1304 on the PCB 804 may include the hole 828, which allows the first heat dissipation unit 812 to extend through the PCB 804 and contact the cable connector 724 inserted within the cage body 808.

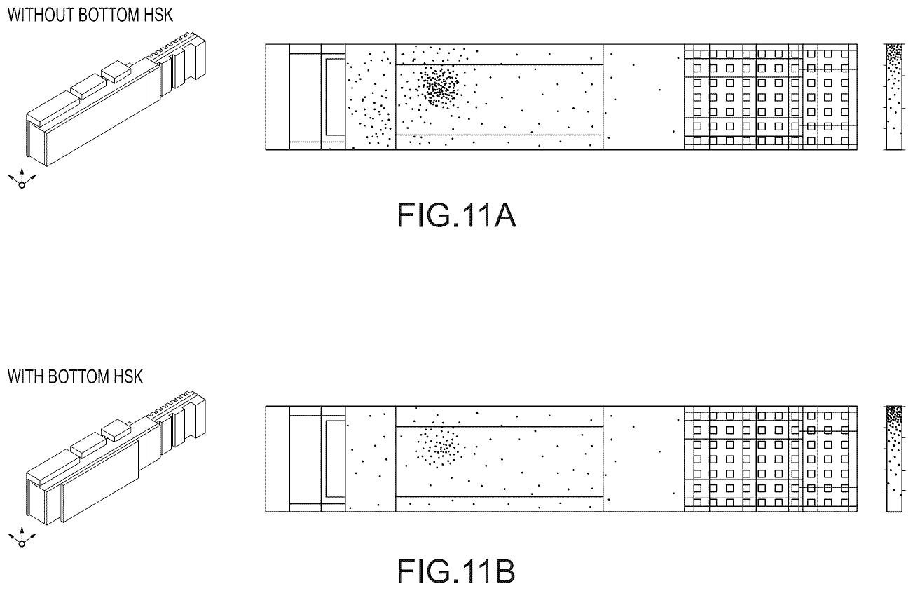

As can be seen in FIGS. 11A and 11B, the inclusion of a first heat dissipation unit 812 to cool a bottom side of the cage body 808 and/or the cable connector 724 inserted therein helps to improve the thermal performance of the cage receptacle assembly 800. More specifically, as shown in FIG. 11A, without a first heat dissipation unit 812 (e.g., without a bottom heatsink), heat generated by the cable connector 724 and other components on the PCB 804 may result in higher temperatures across the PCB 804, across the cage body 808, and/or within the cable connector 724. Conversely, as shown in FIG. 11B, the inclusion of a first heat dissipation unit 812 to remove heat from the bottom side 732 of the cable connector 724 helps to improve the thermal performance of the PCB 804, the cage body 808, and/or the cable connector 724. Such improvements in thermal performance can help minimize damage to components of the cage receptacle assembly 800 and/or the cable connector 724.

FIGS. 9A-10 illustrate additional details of the securing elements 820, 824. The securing elements 820, 824 are shown to be connectable to one another, thereby providing an ability to assemble the cage receptacle assembly 800 in a manner such that each securing element 820, 824 applies the same force on both heat dissipation units 812, 816. The illustrated configuration of the securing elements 820, 824 enables the first heat dissipation unit 812 and the second heat dissipation unit 816 to be independently adjustable with respect to the cage body 808 and/or cable connector 724. Because the securing elements 820, 824 hold other components of the cage receptacle assembly 800 in place, the heat dissipation units 812, 816 are configured to float/ride, meaning the heat dissipation units 812, 816 are independently adjustable relative to the cage body 808 and/or cable connector 724.

FIG. 10 specifically illustrates one particular configuration of securing elements 820, 824 in accordance with at least some embodiments of the present disclosure. The securing elements 820, 824 are shown to include one or more leaf springs (e.g., as components of the second securing element 824), which connect with one or more retention mechanisms (e.g., as components of the first securing element 820) to create a force (e.g. mutual attachment) that secures the heat dissipation units 812, 816 together and to the PCB 804. In some embodiments, the first securing element 820 may include one or more tabs 1004 that click into, latch onto, or otherwise form a friction fit with one or more notches or holes 1008 provided in the second securing element 824. Once connected, the securing elements 820, 824 may cooperate with one another to provide securing forces to other components of the cage receptacle assembly 800. Collectively the securing elements 820, 824 may be referred to as a collective retention mechanism 1000.

In embodiments, the first heat dissipation unit 812 and the securing elements may be different parts that connect with one another. In other embodiments, the securing elements may be integrally formed as part of a heat dissipation unit. In other embodiments, where the heat dissipation unit and the retention mechanisms are comprised of a single part.

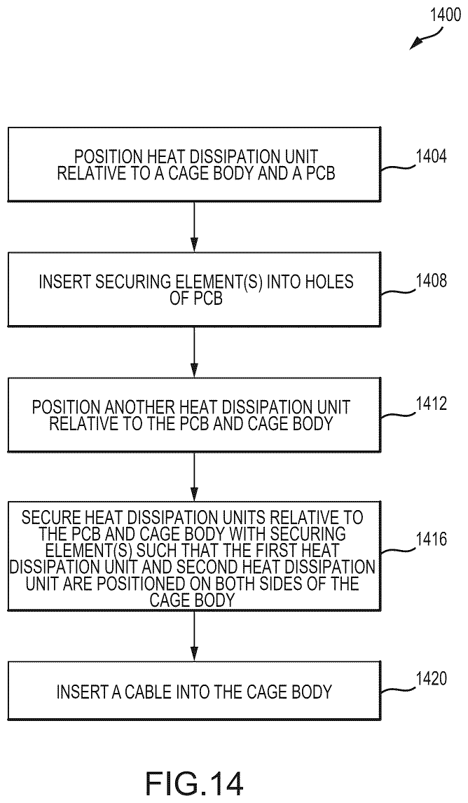

Referring now to FIG. 14, an illustrative but non-limiting example of a method 1400 of constructing a cage receptacle assembly will be described in accordance with at least some embodiments of the present disclosure. The cage receptacle assembly manufactured according to the method 1400 may correspond to one or more of the cage receptacle assemblies (e.g., assembly 600, 800, etc.) depicted and described herein.

The method 1400 may be relevant to the assembly stages of a cage receptacle assembly (e.g., assembly 600, 800, etc.) as shown in FIGS. 8A-E and/or FIGS. 9A-D. The steps of method 1400 may be performed in any suitable order without departing from the scope of the present disclosure. Alternatively or additionally, two or more steps of method 1400 may be performed simultaneously or substantially simultaneously without departing from the scope of the present disclosure.

The method 1400 may include positioning a heat dissipation unit relative to a cage body and a PCB (step 1404). The cage body may correspond to cage body 608 or cage body 808. The PCB may correspond to PCB 604 or PCB 804. The heat dissipation unit may correspond to the first heat dissipation unit 812 or second heat dissipation unit 816.

The method 1400 may further include positioning one or more securing elements relative to the heat dissipation unit, PCB, and cage body (step 1408). For instance, one or more securing elements, such as securing elements 820 may be inserted through one or more holes of the PCB to maintain an alignment of the heat dissipation unit relative to the PCB and/or cage body.

The method 1400 may further include positioning another heat dissipation unit relative to the cage body and PCB (step 1412). In this step, the heat dissipation unit may correspond to the other heat dissipation unit that was not positioned in step 1404. For example, if the first heat dissipation unit 812 was positioned in step 1404, then the second heat dissipation unit 816 may be positioned in step 1412. Conversely, if the second heat dissipation unit 816 was positioned in step 1404, then the first heat dissipation unit 812 may be positioned in step 1412. Regardless, the combination of steps 1404 and 1412 may result in the cage body and PCB being sandwiched between two heat dissipation units.

The method 1400 may further include securing the heat dissipation units relative to the PCB and the cage body using one or more securing elements (step 1416). In some embodiments, a combination of securing elements 820 and 824 are used to apply a securing force on a top side of one of the heat dissipation units toward the other heat dissipation unit. In this way, the heat dissipation units are provided on opposing sides of the cage body and PCB with sufficient forces to maintain a position of the heat dissipation units, but to also allow one or both of the heat dissipation units to “float” and accommodate a cable inserted into the cage body. In other words, the securing elements may help push one or both of the heat dissipation units inwardly, toward the cage body and cable when a cable is inserted into the cage body.

Thus, the method 1400 may further include inserting a cable into the cage body (step 1420). More specifically, and without limitation, the method 1400 may include inserting a cable connector 724 into the cage body such that a top side and/or a bottom side of the cable connector 724 are in physical and/or thermal contact with a first heat dissipation unit and/or a second heat dissipation unit.

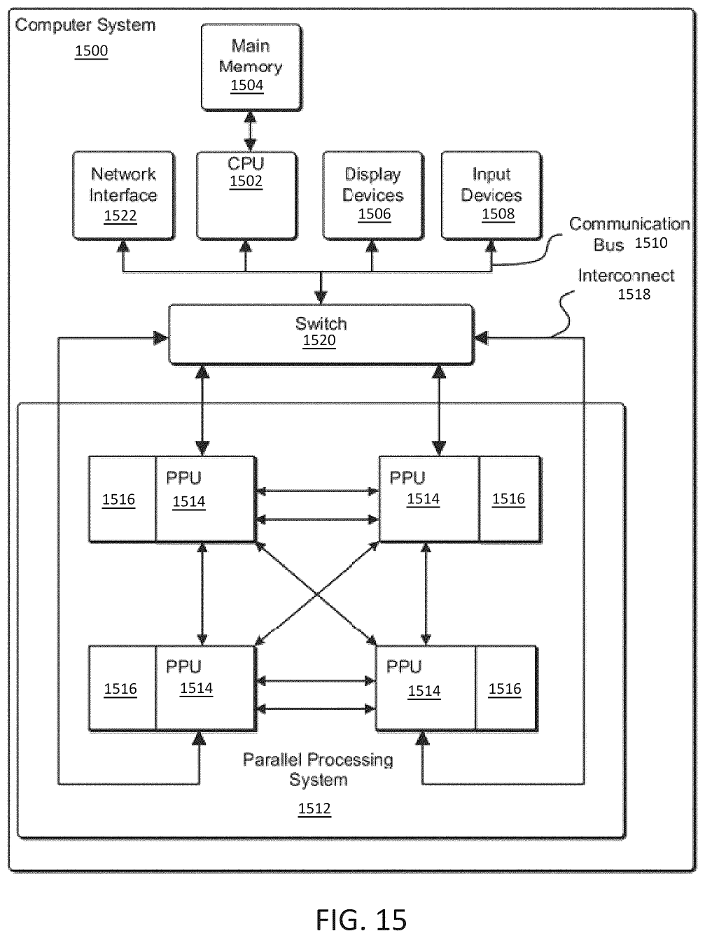

FIG. 15 illustrates an example system in which embodiments of the present disclosure may be deployed. Specifically, FIG. 15 illustrates a computer system 1500, according to at least one embodiment. In at least one embodiment, computer system 1500 is configured to implement various processes and methods described throughout this disclosure.

In at least one embodiment, computer system 1500 comprises, without limitation, at least one central processing unit (“CPU”) 1102 that is connected to a communication bus 1510 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1500 includes, without limitation, a main memory 1504 and control logic (e.g., implemented as hardware, software, or a combination thereof) and data are stored in main memory 1504 which may take form of random access memory (“RAM”). In at least one embodiment, a network interface subsystem (“network interface”) 1522 provides an interface to other computing devices and networks for receiving data from and transmitting data to other systems from computer system 1500.

In at least one embodiment, computer system 1500, in at least one embodiment, includes, without limitation, input devices 1508, parallel processing system 1512, and display devices 1506 which can be implemented using a conventional cathode ray tube (“CRT”), liquid crystal display (“LCD”), light emitting diode (“LED”), plasma display, or other suitable display technologies. In at least one embodiment, user input is received from input devices 1508 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1504 and/or secondary storage. Computer programs, if executed by one or more processors, enable system 1500 to perform various functions in accordance with at least one embodiment. memory 1504, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1502; parallel processing system 1512; an integrated circuit capable of at least a portion of capabilities of both CPU 1502; parallel processing system 1512; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 1500 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1512 includes, without limitation, a plurality of parallel processing units (“PPUs”) 1514 and associated memories 1516. In at least one embodiment, PPUs 1514 are connected to a host processor or other peripheral devices via an interconnect 1518 and a switch 1520 or multiplexer. In at least one embodiment, parallel processing system 1512 distributes computational tasks across PPUs 1514 which can be parallelizable-for example, as part of distribution of computational tasks across multiple graphics processing unit (“GPU”) thread blocks. In at least one embodiment, memory is shared and accessible (e.g., for read and/or write access) across some or all of PPUs 1514, although such shared memory may incur performance penalties relative to use of local memory and registers resident to a PPU 1514. In at least one embodiment, operation of PPUs 1514 is synchronized through use of a command such as_syncthreads( ), wherein all threads in a block (e.g., executed across multiple PPUs 1514) to reach a certain point of execution of code before proceeding.

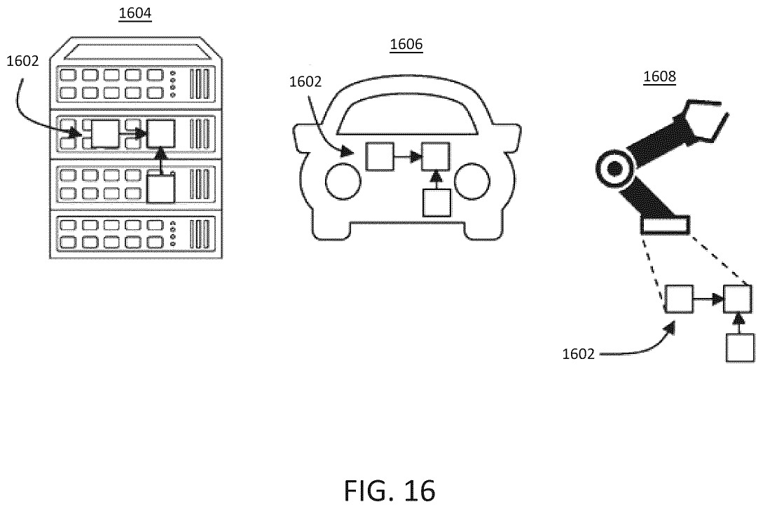

FIG. 16 illustrates another example environment in which embodiments of the present disclosure may be deployed. In particular, embodiments of the present disclosure may be deployed in one or more optical transceiver technologies. Illustratively, and without limitation, embodiments of the present disclosure may be deployed in an optical transceiver 1602 in accordance with some embodiments. An optical transceiver 1602 may be utilized in a computing system 1604 (e.g., in a server farm, or within a server computer system), a vehicle 1606 (e.g., a car, truck, train, or airplane), and a robot 1608 (or among robots in a factory), to name just a few examples. The optical transceiver 1602 may be particularly useful for high-speed communication in environments subject to high levels of electromagnetic interference (EMI).

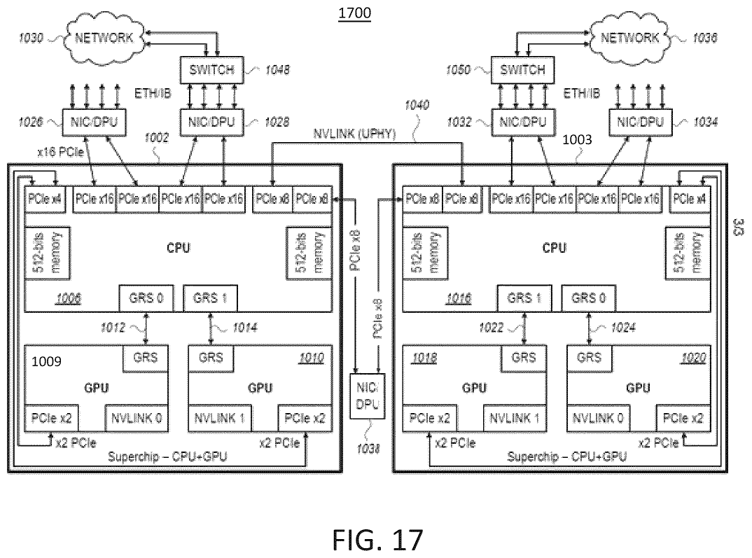

FIG. 17 illustrates yet another example environment in which embodiments of the present disclosure may be deployed. In particular, embodiments of the present disclosure may be deployed in a computing system, such as a data center or a High-Performance Computing (HPC) cluster.

Computing system 1700 represents one example of a system in which embodiments of the present disclosure may be deployed. The computing system 1700 is shown to include a plurality of subsystems, e.g. multiple processing devices coupled to each other, multiple network devices, and multiple networks, according to at least one embodiment. Computing system 1700 is designed with multiple integrated circuits (referred to as processing devices), where each integrated circuit can include one or more CPUs and GPUs, forming a powerful and flexible architecture.

The various processing devices may be interconnected via an NVLink or other high-speed interconnect, enabling high-speed communication between the subsystems, and are also connected through a NIC or DPU to ensure efficient data transfer across computing system 1700 and to one or more external networks 1030, 1036. In the present example, system 1700 comprises a packet switch 1048 that connects NIC/DPU 1028 to network 1030, and a packet switch 1050 that connects NIC/DPU 1032 to network 1036.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1700 can include one or more CPUs and one or more GPUs.

FIG. 17 also demonstrates an example architecture of a multi-GPU architecture. As illustrated in the figure, computing system 1000 includes a processing device 1002 with a multi-GPU architecture. In particular, processing device 1002 may be a system-on-chip and includes multiple subsystems such as a CPU 1006, a GPU 1009, and a GPU 1010. CPU 1006 can be coupled to GPU 1009 via a die-to-die (D2D) or chip-to-chip (C2C) interconnect 1012, such as a Ground-Referenced Signaling interconnect (GRS interconnect). CPU 1006 can be coupled to GPU 1010 via a D2D or C2C interconnect 1014. CPU 1006 can also couple to GPU 1008 and GPU 1010 via PCIe interconnects.

CPU 1006 can be coupled to one or more NICs or DPUs, which are coupled to one or more networks. For example, as illustrated in FIG. 17, CPU 1006 is coupled to a first NIC/DPU 1026, which is coupled to a network 1030. CPU 1006 is also coupled to a second NIC/DPU 1028, which is coupled to network 1030 via switch 1048. NIC/DPU 1026 and NIC/DPU 1028 can be coupled to network 1030 over Ethernet (ETH), NVLINK or InfiniBand (IB) connections, for example.

Computing system 1700 also includes a processing device 1003 with a multi-GPU architecture. In particular, processing device 1003 includes multiple subsystems including a CPU 1016, a GPU 1018, and a GPU 1020. CPU 1016 can be coupled to GPU 1018 via an D2D or C2C interconnect 1022. CPU 1016 can be coupled to GPU 1020 via a D2D or C2C interconnect 1024. CPU 1016 can also couple to GPU 1018 and GPU 1020 via PCIe interconnects. CPU 1016 can be coupled to one or more NICs or DPUs, which are coupled to one or more networks. For example, as illustrated in FIG. 17, CPU 1016 is coupled to a first NIC/DPU 1032, which is coupled to a network 1036. CPU 1016 is also coupled to a second NIC/DPU 1034, which is coupled to network 1036 via switch 1050. NIC/DPU 1032 and NIC/DPU 1034 can be coupled to network 1036 over Ethernet (ETH), NVLINK or InfiniBand (IB) connections.

In at least one embodiment, processing device 1002 and processing device 1003 can communicate with each other via a NIC/DPU 1038, such as over PCIe interconnects. Processing device 1002 and processing device 1003 can also communicate with each other over a high-bandwidth communication interconnects 1040, such as an NVLink interconnect or other high-speed interconnects. The packet switches in FIG. 17 may comprise, for example, Nvidia Quantum-2 switches. The NICs/DPUs in the figure may comprise, for example, Nvidia Bluefield DPUs. Interconnections between one or more of the devices illustrated in FIG. 17 may be supported with a thermally-efficient interconnect device or cage receptacle assembly.

The present disclosure contemplates that the present disclosure may be created from any suitable material known in the art (e.g., carbon steel, aluminum, polymers, ceramics, and the like), particularly materials possessing high thermal conductivity. By way of example, the cage receptacle assembly may be created by an extrusion and/or machine process. In such an example, a single body of fixed cross-sectional area may be produced by an extrusion process. This single body may be created via pushing a base material (e.g., a polymer) through a dimensioned die such that the cage body of the cage receptacle assembly is created. In some embodiments, the single body may be created as two separate elements (e.g., a top cage member and bottom cage member) where the two separate elements are further attached to form the single body. This extruded body may then be modified through a machine process whereby material is removed from the extruded body to create the finished cage receptacle assembly. The machining process may include any or all of micro machining, turning, milling, drilling, grinding, water jet cutting, EDM, EDM, AFM, USM, CNC, and the like, in any order or combination. Although described as an extrusion and machine process of a single piece of material, any portion or sub-portion of the cage receptacle assembly may be separately formed or attached without departing from the scope of this disclosure.

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components (e.g., components of printed circuit boards, transceivers, cables, etc.) may be used in conjunction with the cage receptacle assembly. Therefore, it is to be understood that the disclosures are not to be limited to the specific embodiments disclosed and that modifications and other embodiments are intended to be included within the scope of the appended claims.

It is to be appreciated that any feature described herein can be claimed in combination with any other feature(s) as described herein, regardless of whether the features come from the same described embodiment.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A cage receptacle assembly comprising:
a cage body;
a first heat dissipation unit disposed proximate to a bottom side of the cage body and configured to remove heat from the bottom side of the cage body; and
a second heat dissipation unit disposed proximate to a top side of the cage body and configured to remove heat from the top side of the cage body.

2. The cage receptacle assembly according to claim 1, further comprising a Printed Circuit Board (PCB).

3. The cage receptacle assembly according to claim 2, wherein the first heat dissipation unit is provided on a bottom side of the PCB and extends through a hole of the PCB.

4. The cage receptacle assembly according to claim 3, wherein the cage body comprises a hole on a bottom side thereof that substantially aligns with the hole of the PCB and wherein the first heat dissipation unit extends through the hole of the cage body.

5. The cage receptacle assembly according to claim 4, wherein the first heat dissipation unit is configured to contact a bottom side of a cable connector inserted into the cage body.

6. The cage receptacle assembly according to claim 5, wherein the cage body is provided on a top side of the PCB.

7. The cage receptacle assembly according to claim 6, wherein the bottom side of the cage body abuts the top side of the PCB and wherein the top side of the cage body comprises an opening though which the second heat dissipation unit is configured to extend through to contact a top side of the cable connector.

8. The cage receptacle assembly according to claim 1, further comprising a first portion of a securing element that wraps around at least a portion of the first heat dissipation unit and that secures the first heat dissipation unit to the cage body.

9. The cage receptacle assembly according to claim 8, further comprising a second portion of the securing element that wraps around at least a portion of the second heat dissipation unit and that secures the second heat dissipation unit to the cage body.

10. The cage receptacle assembly according to claim 9, wherein the first portion of the securing element and the second portion of the securing element cooperate to secure the first heat dissipation unit and the second heat dissipation unit to the cage body.

11. The cage receptacle assembly according to claim 9, wherein the first portion of the securing element and the second portion of the securing element cooperate to secure the first heat dissipation unit and the second heat dissipation unit to a Printed Circuit Board (PCB) on which the cage body is provided.

12. The cage receptacle assembly according to claim 1, wherein the cage receptacle assembly is configured to receive a cable connector, the cable connector comprising an octal small form factor pluggable (OSFP) or a quad small form factor pluggable (QSFP).

13. The cage receptacle assembly according to claim 1, wherein the cage body is constructed of sheet metal.

14. The cage receptacle assembly according to claim 1, wherein the first heat dissipation unit comprises a first portion and a second portion, wherein the first portion of the first heat dissipation unit extends through a hole of the cage body, and wherein the second portion of the first heat dissipation unit comprises a finned structure.

15. The cage receptacle assembly according to claim 1, wherein the second heat dissipation unit comprises a finned structure.

16. The cage receptacle assembly according to claim 1, wherein the first heat dissipation unit comprises a portion of a securing element integrated therewith.

17. The cage receptacle assembly according to claim 1, wherein the second heat dissipation unit comprises a portion of a securing element integrated therewith.

18. The cage receptacle assembly according to claim 1, further comprising:
a securing element that secures the first heat dissipation unit and/or the second heat dissipation unit to the cage body such that one or both of the first heat dissipation unit and the second heat dissipation unit are independently adjustable relative to the cage body.

19. The cage receptacle assembly according to claim 18, wherein the securing element comprises a first portion and a second portion that cooperate with one another to flexibly hold the first heat dissipation unit and the second heat dissipation unit to the cage body in a manner that accommodates a cable connector to move one or both of the first heat dissipation unit and the second heat dissipation unit when the cable connector is inserted into the cage body.

20. A method comprising:
providing a first heat dissipation unit on a first side of a cage body;
providing a second heat dissipation unit on a second side of the cage body; and
securing the first and second heat dissipation units to the cage body in a manner that accommodates a cable connector to move one or both of the first heat dissipation unit and the second heat dissipation unit when the cable connector is inserted into the cage body.
